(19) United States
(12) Patent Application Publication
(10) Pub. No.: US 2023/0207402 A1
(43) Pub. Date: Jun. 29, 2023

(54) DIRECTLY BONDED FRAME WAFERS

(71) Applicant: ADEIA SEMICONDUCTOR BONDING TECHNOLOGIES INC., San Jose, CA (US)

(72) Inventors: Gaius Gillman Fountain, JR., Youngsville, NC (US); Guilian Gao, San Jose, CA (US); George Carlton Hudson, San Jose, CA (US); Laura Wills Mirkarimi, Sunol, CA (US)

(21) Appl. No.: 18/146,326

(22) Filed: Dec. 23, 2022

Related U.S. Application Data
(60) Provisional application No. 63/294,031, filed on Dec. 27, 2021.

(51) Int. Cl. H01L 23/04; H01L 21/48; H01L 21/52

(52) U.S. Cl. CPC H01L 23/04; H01L 21/486; H01L 21/52

(57) ABSTRACT

A bonded structure comprises a frame element having a cavity formed through its thickness. The frame element is directly bonded to a first element at a first side and to a second element at a second side enclosing the cavity. The frame element may comprise a through substrate via (TSV). Redundant conductive contact pads may be formed in bonding layers for enhanced direct bonding quality and reliability.

### CROSS REFERENCE TO RELATED APPLICATION

This patent application claims the benefit of U.S. Provisional Application No. 63/294,031, filed Dec. 27, 2021, the entire contents of which are hereby incorporated by reference in their entirety and all purposes.

### BACKGROUND

### Field

The field relates to directly bonded frame wafers.

### Description of the Related Art

Many electronic devices include fluid-filled or gas-filled cavities. For example, in some applications, it can be beneficial to provide integrated device dies within air-filled cavities, as opposed to overmolding the dies, so as to avoid thermally-induced stresses or for other considerations. As another example, some microelectromechanical systems (MEMS) devices include cavities for applications such as microphones, gas sensors, or the like. Many other types of devices utilize air-filled cavities. Accordingly, there remains a continuing demand for electronic devices with cavities.

### BRIEF DESCRIPTION OF THE DRAWINGS

Specific implementations will now be described with reference to the following drawings, which are provided by way of example, and not limitation.

FIGS. 1-7 are a set of schematic cross-sectional views illustrating a first embodiment of a process for forming a bonded structure comprising a frame element (e.g., a frame semiconductor element) stacked between a first semiconductor element and a second semiconductor element.

FIG. 8-10B are schematic cross-sectional views of alternative process steps to FIG. 2 and FIG. 3.

FIGS. 11-17 are another set of schematic cross-sectional views illustrating the second embodiment process for forming a bonded structure comprising a framed element stacked between a first semiconductor element and a second semiconductor element.

FIGS. 18-21 are schematic cross-sectional views of alternative process steps to FIG. 15 and FIG. 16.

FIGS. 22-24 are schematic cross-sectional views of alternative process steps to FIG. 13, FIG. 14, and FIG. 16.

FIGS. 25-30 are schematic cross-sectional views of alternative process steps to FIGS. 11-17.

FIGS. 31-35 are another set of schematic cross-sectional views illustrating a third embodiment process for forming a bonded structure comprising a framed semiconductor element stacked between a first semiconductor element and a second semiconductor element.

FIGS. 36-41 are yet another set of schematic cross-sectional views illustrate a fourth embodiment process for forming a bonded structure comprising a framed semiconductor element stacked between a first semiconductor element and a second semiconductor element.

FIGS. 42-48 are cross-sectional views illustrating various types of structures of conductive contact pads connected with through substrate vias (TSVs).

FIG. 49 and FIG. 50 are cross-sectional views illustrating two bonded structures each comprising a frame element having redundant contact pads directly bonded to a first element and a second element.

FIG. 51 is a schematic cross-sectional view of two microelectronic elements configured to be directly bonded together.

FIG. 52 is a schematic cross-sectional view of bonded structure comprising the two microelectronic elements in FIG. 51 bonded together.

### DETAILED DESCRIPTION

As the industry moves toward higher speed devices and computation, there is a need for continued footprint size reduction and efficient interconnect between dies that are stacked vertically. Advanced packaging of multi-functional modules stacks devices vertically. For example, a silicon interposer is an effective way to provide communication between side-by-side dies and between stacked elements or devices. Nevertheless, there is a continuing need for structures that improve integration of multiple devices or modules. Accordingly, in various embodiments, a frame wafer or frame interposer with an interconnect can be provided between stacked wafers or interposers. The frame wafer can provide efficient integration of multi-level wafers and electronic devices. The frame wafer disclosed herein can effectively create a cavity in an electronic device. Electronic devices with cavities (e.g., fluid-filled cavities, such as gas or liquid filled cavities) can be used in numerous types of applications, such as microelectromechanical systems (MEMS) devices, sensors (e.g., gas sensors, pressure transducers, biological sensors, etc.), microfluidic devices, microphone packages, speaker devices, fluid cooling devices, or any other suitable device in which a fluid-filled cavity is used.

Various embodiments disclosed herein relate to a bonded structure that may include a frame semiconductor element, e.g., a frame wafer, a first semiconductor element directly bonded to the frame element at a first side, and a second semiconductor element directly bonded to the frame element at a second side opposite the first side. An opening can be formed through the frame element such that, when the first and second elements are bonded to the frame element, the opening at least partially defines a cavity. In various embodiments, the frame element may be relatively thin, and/or the opening may have a large width. For example, in various arrangements, the opening may have a width in a range of 0.5 mm to 30 mm. The large hole and/or the small thickness of the frame element may make it challenging to handle and prone to damaging, warping, or breaking the frame element. Accordingly, various embodiments disclosed herein include various methods and structures for handling the frame element and directly bonding the frame element to other element(s). The frame element can be part of any suitable type of electronic device, such as a radio frequency integrated device, a microelectromechanical systems (MEMS) device, or any other suitable type of device, in form of a wafer or a die.

In another embodiment, a method can include providing a frame element having a bulk portion, a first bonding layer disposed on a first surface of the bulk portion and at least partially defining a first side of the frame element, and a second bonding layer on a second surface of the bulk portion and at least partially defining a second side of the frame element opposite the first side. As explained herein, an opening can be formed through the frame element such that the opening extends through the first bonding layer, the bulk portion, and the second bonding layer.

In various embodiments, the bulk portion may comprise a semiconductor material, e.g., a silicon, a glass, a ceramic, or any other suitable type of material. In various embodiments, the first bonding layer may comprise a first nonconductive or dielectric material layer with a first conductive contact feature at least partially embedded in the first nonconductive layer. The second bonding layer can comprise a second nonconductive or dielectric material layer with a second conductive contact feature at least partially embedded in the second nonconductive layer. A conductive through substrate via (TSV) can extend through the frame element, the TSV including or connected to the first and second conductive contact features (which may comprise exposed ends of the TSV). Additionally, or alternatively, the conductive contact features can comprise discrete metallic pads formed in the bonding layer(s) and connected to underlying metallization in back-end-of-line (BEOL) layer(s). In various embodiments, at least one of the first and second nonconductive layers comprises silicon oxide. As explained herein, the first and second bonding layers can be prepared for direct bonding, e.g., the first and second bonding layers can be polished and activated for direct bonding.

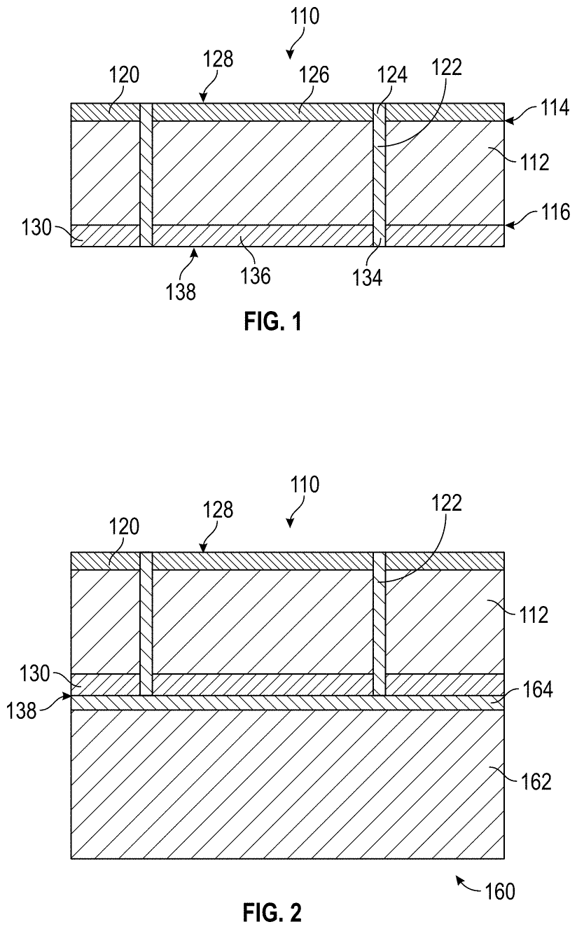

Various embodiments are disclosed herein to illustrate example processes for forming vertically stacked devices using frame elements. A set of example embodiment process steps are illustrated in FIGS. 1-7 as cross-sectional views. For example, the frame element can be mounted to a temporary substrate by way of an adhesive. In initial 3 steps, an opening can be formed with the frame element on the substrate by etching through the first bonding layer in a first direction from the first side of the frame element towards the second side of the frame element, etching completely through the bulk portion in the first direction, and etching through the second bonding layer in the first direction. Any suitable etch processes can be used. In the illustrated embodiment, a dry etch process can be used, which can stop on the adhesive shown in Process.

Referring to FIG. 1, a schematic cross-sectional view of a frame semiconductor element 110 is shown. The frame element 110 comprises a bulk portion 112 having a first surface 114 and a second surface 116 opposite the first surface 114, a first bonding layer 120 disposed on the first surface 114, and a second bonding layer 130 disposed on the second surface 116. The first bonding layer 120 may comprise a conductive contact feature 124 embedded in a nonconductive or dielectric material layer 126, forming a first planarized bonding surface 128. Likewise, the second bonding layer 130 may comprise a conductive contact feature 134 embedded in a nonconductive or dielectric material layer 136, forming a second planarized bonding surface 138. At least one through substrate via (TSV) 122 may extend through the frame element 110 including or connecting to the conductive contact feature 124 at the first surface 128 and to the conductive contact feature 134 at the second bonding surface 138. The frame element 110 may comprise a device, e.g., a microelectromechanical systems (MEMS) device, a sensor, or any other suitable device that utilizes a fluid-filled (e.g., gas-filled or liquid-filled cavity). The bulk portion 112 may be made of a semiconductor material, e.g., silicon, a glass, a ceramic, or any other suitable type of material.

In FIG. 2, the frame element 110 is shown mounted to a temporary support 160, e.g., a handle wafer. The temporary support 160 comprises a support substrate 162, which may be made of semiconductor material, glass, ceramic, or another type of rigid material, e.g., metal, and a temporary bonding layer 164 disposed on the support substrate 162. The temporary bonding layer 164 may comprise an organic or polymeric adhesive material that is laser de-bondable or low temperature flow/knife edge removable. When the frame element 110 or an element to be bonded to the frame element 110 is very thin and fragile, the support 160 provides a temporary support during fabrication processing to prevent damage and/or warpage to the frame element 110 or the bonded element. After various process steps, the support 160 is removed from the frame element 110.

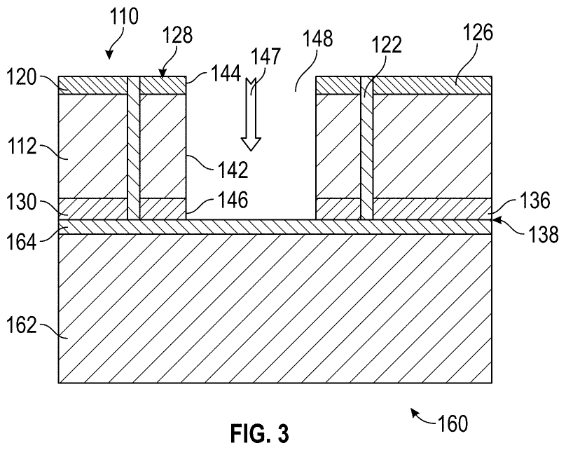

FIG. 3 shows that after the frame element 110 is mounted to the temporary support 160, an opening 148 may be formed in the frame element 110. This can be done by etching in a first direction 147 from the first side 128 of the frame element 110, through the first bonding layer 120, the bulk portion 112, and the second bonding layer 130, reaching the second side 138 of the frame element 110 and the bonding layer 164. In FIG. 3, all the layers of the frame element 110 can be etched through in one etching step in the first direction 147. Alternatively, different layers can be etched selectively, also in the first direction 147. For example, the first bonding layer 120 can be selectively etched first, followed by the bulk portion 112, and then the second bonding layer 130.

In FIG. 3, the sidewalls of the opening 148 may include a first sidewall 142 for the bulk portion 112, a second sidewall 144 for the first bonding layer 120, and a third sidewall 146 for the second bonding layer 130. In a top view of the frame element 110, the opening 148 may be an enclosed feature, e.g., a round hole. Therefore, the sidewalls 142, 144 and 146 on the left side of the opening or hole 148 can be continuously connected to the sidewalls on the right side of the opening. As illustrated in FIG. 3, the sidewalls 142, 144 and 146 are approximately vertical. These sidewalls may be etched by a reactive ion etching (RIE) method, or any other suitable etching methods that form an approximately vertical sidewall (or a sloped profile as explained below). When a suitable etching method is applied, for example, the first sidewall 142, the second sidewall 144 and the third sidewall 146 can be slightly tapered or sloped, forming a small angle with a vertical reference plane.

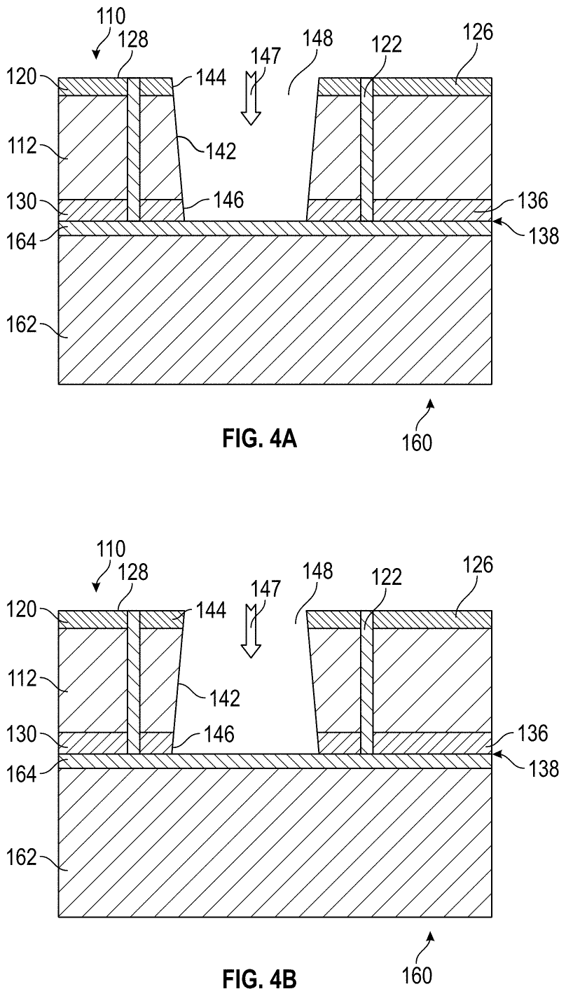

In some embodiments, a wet etch process can be used to form the opening 148. In various types of wet etch processes, as shown in FIG. 4A the etching can cause the sidewalls to taper inwardly as the etch process proceeds downwardly. As such the opening at the top surface 128 can be wider than the opening at the bottom surface 138 in such wet etch processes. In other embodiments, a dry etch process can be used, as shown in FIG. 4B. As shown in the dry etch process of FIG. 4B, in such embodiments, the slope of the sidewalls may be reversed. In dry etch processes, the sidewalls may taper outwardly as the etching process proceeds downwardly, and the formed opening 148 may be smaller at the top surface 128 and wider at the bottom surface 138. It should be appreciated that any of the structures disclosed herein can be formed by a wet etch process or a dry etch process, with the structures' sidewalls being shaped accordingly. For example, the sidewalls can be approximately vertical, can be sloped inwardly with a larger opening at the top surface than the bottom surface (e.g., using various wet etch techniques), or can be sloped outwardly with a smaller opening at the top surface than the bottom surface (e.g., using various dry etch techniques). The etch processes disclosed in FIGS. 4A-4B can be used in combination with any other embodiments disclosed herein

Each of the sidewalls 142, 144 and 146 shown in FIG. 3, FIG. 4A and FIG. 4B may comprise an etching signature related to its etching conditions, including etching direction, etching method and material of the layer being etched. For example, the first sidewall 142 may comprise a first etch signature indicative of etching in the first direction 147 in the bulk portion 112 by an etching method to form the corresponding approximately vertical or slightly tapered sidewall profile. Similarly, the second sidewall 144 may comprise a second etch signature indicative of etching in the first direction 147 in the nonconductive layer 126 by an etching method to form the corresponding approximately vertical or slightly tapered sidewall profile. The third sidewall 144 may comprise a third etch signature indicative of etching in the first direction 147 in the nonconductive layer 136 by an etching method to form the corresponding approximately vertical or slightly tapered sidewall profile. If the nonconductive bonding layer used in the layer 126 is the same as in the layer 136 and the same etching method is applied, the second etch signature may be substantially the same or very similar to the third etch signature because both of them share the same etching direction, as illustrated in FIG. 3, FIG. 4A and FIG. 4B.

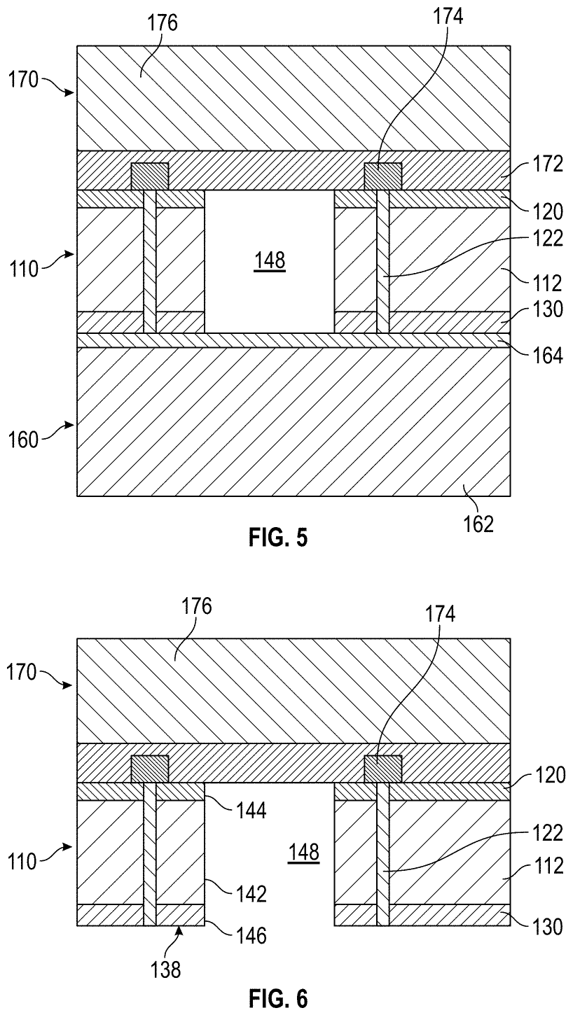

As shown in FIG. 5, a first semiconductor element 170, e.g., a wafer or a die, can be directly bonded to the first bonding layer 120 of the frame element 110 over the opening 148 without an intervening adhesive. During the process step of direct bonding, the conductive contact feature or contact pad 174 of the first element 170 may be directly bonded to the conductive contact feature 124 of the frame element 110. The nonconductive bonding layer 172 of the first element 170 may be directly bonded to the nonconductive layer 126 of the frame element 110. Or part of the nonconductive feature of one element may be bonded to part of the conductive feature of the other element. The first element 170 may comprise a device layer 176 having an integrated circuit.

In FIG. 6, the temporary support 160 is removed from the frame element 110 to expose the opening 148 formed in the frame element 110 from the underside. As discussed above, the temporary bonding layer 164 of the support 160 is made of an organic or polymeric adhesive material and can be de-bonded or removed in any suitable manner, e.g., by using a laser, a fluid, or a mechanical technique. After removal of the support 160, a touch-up chemical mechanical polish (CMP) may be applied to remove the adhesive debris from and restore the topography of the second bonding surface 138 so that the second bonding layer 130 of the frame element 110 is ready for direct bonding again.

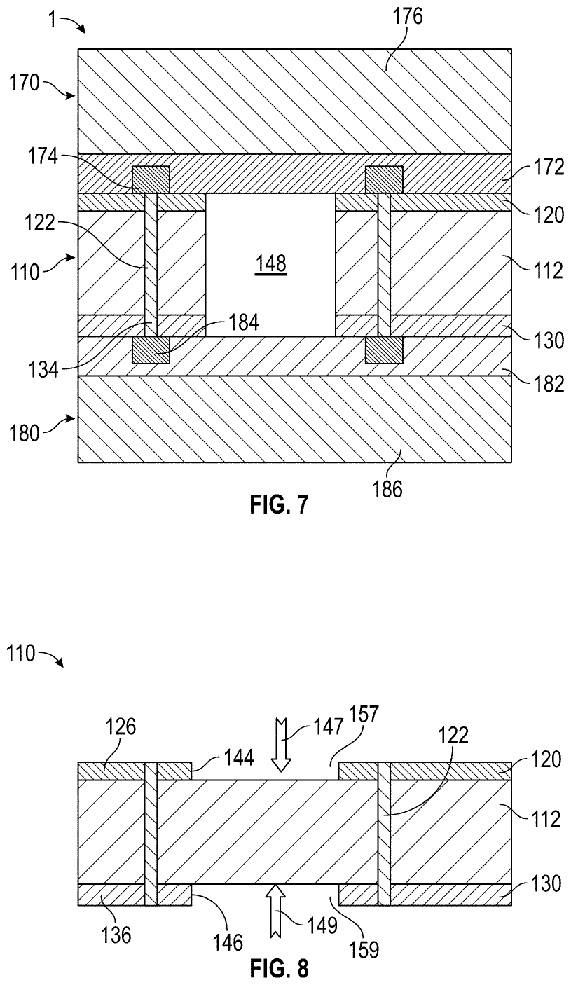

In FIG. 7, a second element 180, e.g., a wafer or a die, can be directly bonded to the second bonding layer 130 of the frame element 110 over the opening 148 without an intervening adhesive so that the opening 148 is enclosed as an internal cavity 148. As such a bonded structure 1 is formed. Similar to the case for the first element 170, the conductive contact feature or contact pad 182 of the second element 180 may be directly bonded to the conductive contact feature 134 of the frame element 110. The nonconductive bonding layer 182 of the second element 180 may be directly bonded to the nonconductive layer 136 of the frame element 110. The second element 180 may comprise a device layer 186 having an embedded metallization layer formed therein, e.g., an integrated circuit. In some embodiments, the frame element 110 stacked in the bonded structure 1 of FIG. 7 may comprise at least one cavity 148. In some embodiments, the frame element 110 in the bonded structure 1 of FIG. 7 may comprise a plurality of the cavities 148. In some embodiment, the bonded structure 1 of FIG. 7 may comprise at least one element bonded to one side of the frame element 110, leaving the opening 148 exposed on the other side of the frame element 110. In some embodiments, one or more devices can be mounted to or formed with at least one of the first and second elements. The one or more devices can extend into or be exposed to the cavity 148. In some embodiments, the one or more devices can comprise an integrated device die.

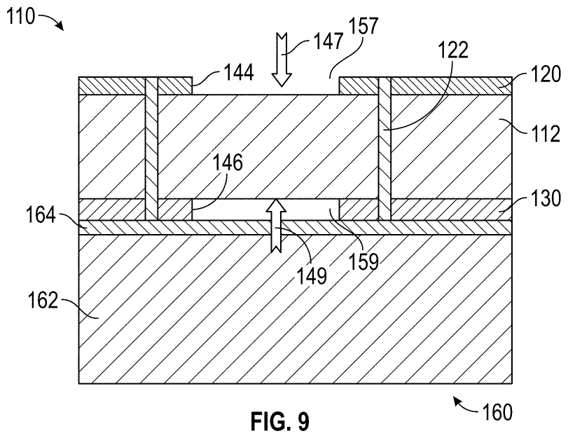

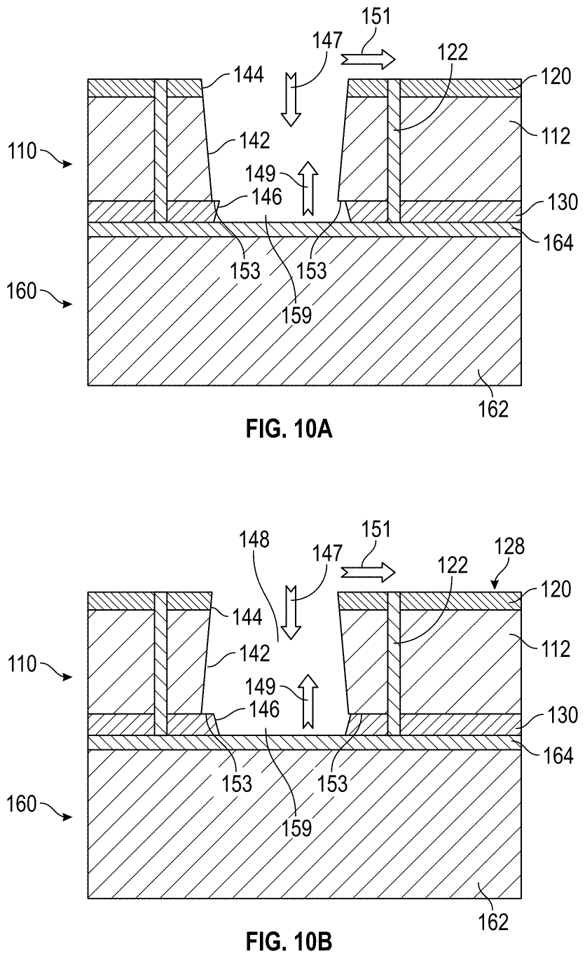

An alternative embodiment of the process steps illustrated in FIGS. 1-4 is illustrated in FIGS. 8-10. As shown in FIG. 8, after the process step of FIG. 1 and before bonding to a temporary support, the first dielectric material layer 126 and the second dielectric material layer 136 can be etched to form corresponding cavities 157 and 159. The first dielectric material layer 126 is etched in the first direction 147, forming a cavity 157 surrounded by the second sidewall 144. The second dielectric material layer 136 is etched in the second direction 149, forming a cavity 159 surrounded by the third sidewall 146. In FIG. 9, the temporary support 160 can be bonded to the frame element 110 in the same way as shown in and explained with respect to FIG. 2. After that, the bulk portion 112 of the frame element 110 is etched in the first direction 147 forming first sidewall 142, as shown in FIG. 10A. If a wet etching method is applied to cause slightly tapered sidewalls, for example, the first sidewall 142 and the second sidewall 144 may taper inwardly as etching proceeds in the first direction 147. The third sidewall 146 may have a reversed angle as compared with the first sidewall 142 and the second sidewall 144 because of the different etching directions 147 and 149. In other embodiments, e.g., when a dry etching method is applied, as shown in FIG. 10B the sidewalls may taper outwardly from the top surface 128 of the bonding layer 120 going downward. In this way, the tapering of the sidewalls 144 and 142 may cause the opening 148 to be smaller at the top than at the bottom. The third sidewall 146 may have a reversed tapering causing the top portion of the opening 150 to be slightly larger than the bottom portion.

Since etching is performed in opposite directions, there may exist a slight misalignment between the first sidewall 142 and the third sidewall 146. As shown in FIG. 10A and FIG. 10B, this misalignment between the first sidewall 142 and the third sidewall 146 is a lateral misalignment, e.g., misalignment in a third direction 151 that is about perpendicular to the first direction 147 and the second direction 149. Because the first and second nonconductive layers 126 and 136 are etched in opposite directions, the layers 126, 136 may be separately masked and patterned. It can be challenging to exactly align the masking and patterning on opposing sides of the frame element 110. The etch processes may therefore create the second sidewall 144 and third sidewall 146 that are also laterally misaligned along the third direction 151. This misalignment is carried on by the masking and patterning of the bulk portion 112 to create the first sidewall 142 and presented at the interface between bulk portion 112 and the second nonconductive layer 136 as the misalignment between the first sidewall 142 and the third sidewall 146 in the third direction 151.

Also, the etch signature of the third sidewall 146 in FIG. 10A and FIG. 10B may be different from the etch signature of the same sidewall in FIG. 3, FIG. 4A or FIG. 4B because the third sidewall 146 in FIG. 10A and FIG. 10B can be etched in the second direction 149 and the third sidewalls 146 in FIG. 3, FIG. 4A and FIG. 4B can be etched in the first direction 147, which is opposite of the second direction 149. Alternatively, in some embodiments due to different etching methods, the third sidewall 146 and the first sidewall 142 can be tapered in the same orientation, e.g., from broader to narrower in the second direction 149. In some embodiments, the taper angle of the first sidewall 142 of the bulk portion 112 may be different from the taper angle of the second sidewall 144 of the nonconductive layer 126 and the third sidewall 146 of the nonconductive layer 136 due to material differences. In other embodiments, the first sidewall 142 may taper by a different angle, may be substantially straight, or may taper at substantially the same angle as the second sidewall 144 and/or the third sidewall 146. In various embodiments, any of the etch signatures disclosed herein can include respective striations in the corresponding sidewalls, and/or respective tapering angles in the corresponding sidewalls. It should be appreciated, however, that the taper angle or orientation may vary depending on the particular etch process used.

The temporary support 160 disclosed in the process steps illustrated in FIGS. 1-10 for forming the bonded structure 1 with the frame element 110 stacked between two other elements has the advantage of providing physical support to the frame element 110 that is thin and fragile. In this way, damaging and/or distortion of element 110 can be prevented. However, since the organic adhesive layer 164 is used for temporary bonding, any adhesive debris remaining on the second bonding surface 138 of the frame element 110 can affect the bonding between the frame element 110 and the second element 180. Also, the debonding or removal process to remove the temporary support 160 may cause damage to the second bonding surface 138. Therefore, a touch-up chemical mechanical polish (CMP) may be applied to remove the adhesive debris and to restore the second bonding layer 130 of the frame element 110 so that it is ready for direct bonding again.

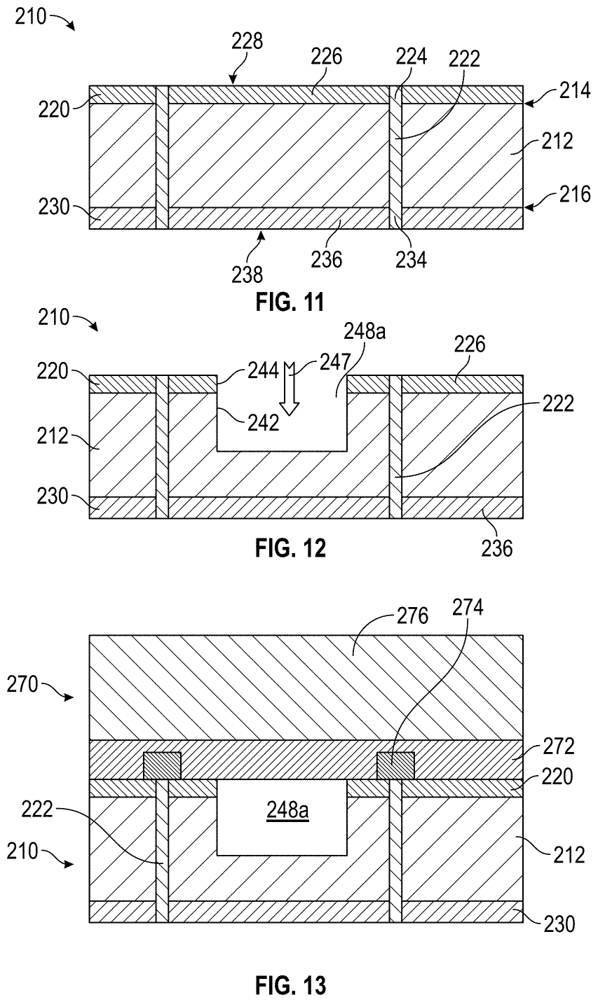

Another set of example embodiment process steps for forming a bonded structure with a cavity in a framed element are illustrated in FIGS. 11-17. To differentiate with the process steps illustrated in FIGS. 1-10, these new set of example embodiment steps are without a temporary support for direct bonding between the frame element and the first element. Similar to the frame element 110 shown in FIG. 1, the example process starts with a frame element 210 as shown in FIG. 11 as a schematic cross-sectional view. Comparing with the frame element 110 in FIG. 1, the frame element 210 in FIG. 11 has substantially the same structure and with reference numerals incremented by 100. Therefore, like reference numerals in FIG. 11 indicate identical or functionally similar structural elements in FIG. 1. For example, in FIG. 11, the frame element 210 comprises a bulk portion 212, a first bonding layer 220, and a second bonding layer 230, comparing to substantially similar elements 112, 120, and 130 of the semiconductor frame element 110 in FIG. 1.

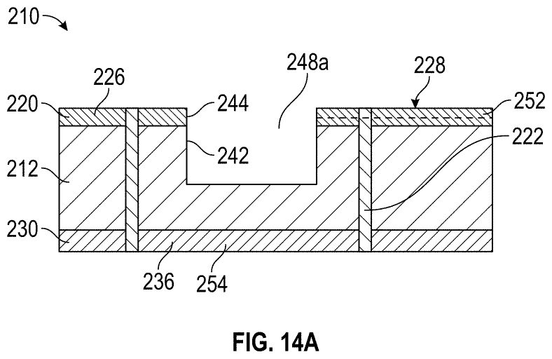

Instead of bonding to a temporary support, in FIG. 12, an opening 248 may be partially etched into the frame element 210 from the first bonding surface 228 in a first direction 247 that is approximately perpendicular to the first bonding surface 228, forming a partial depth opening 248a. For example, the first nonconductive layer 226 and part of the bulk portion 212 can be etched in the first direction 247. As such, a second sidewall 244 can be formed in the nonconductive layer 226, and first sidewall 242 can formed in the partially etched bulk portion 212. Since the partial opening 248a extends only partially through the thickness of the frame element 210, the lower part of the frame element is in one piece and without an opening. Therefore, the frame element 210 may be structured strong enough to be processed further. As illustrated in FIG. 13, after the partial etching to form partial opening 248a, a first element 270 can be directly bonded to the frame element 210. The bonding process may be substantially the same as the bonding of the frame element 110 to the first element 170 as shown in FIG. 5.

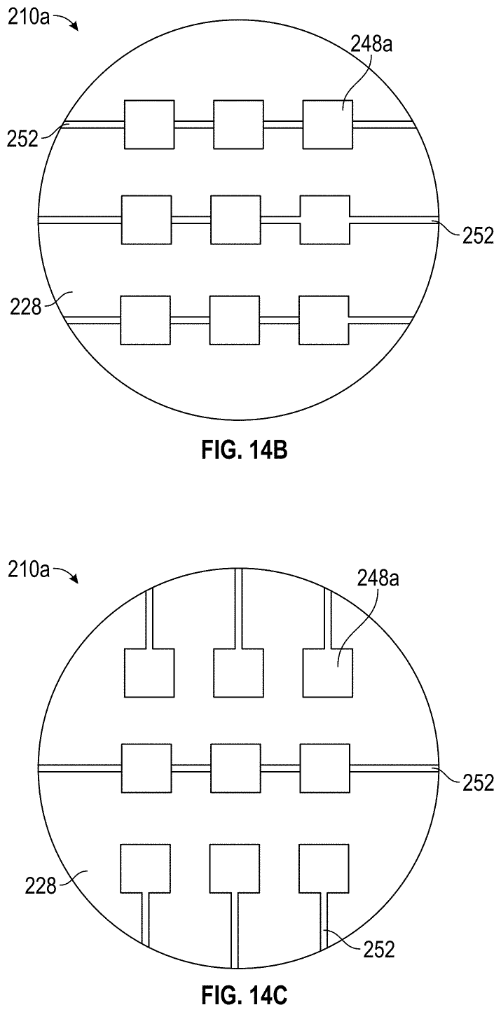

In some embodiments, a venting path may be formed in the frame element 210 to vent air volatile species, e.g., moisture, out of the partial opening 248a. In some embodiments, such a venting path can be provided to relieve pressure such that, when the first element 270 is bonded to the frame element 210, an increase in air pressure and outgassing of volatile chemical in the partial opening 248a during the heated annealing does not cause damage to the thinned portion of the frame element 210 underlying the partial opening 248a. As shown in FIG. 14A, in some embodiments a vent groove 252 may be formed on the bond surface 228 to allow air to flow. FIG. 14B shows a top view of a frame wafer 210a prior to singulation with nine partial depth openings 248a. Grooves 252 horizontally laid out on the top bonding surface 228 of the frame wafer 210a connect each of the nine openings 248a to outside of the wafer perimeter. FIG. 14C illustrates another groove 252 arrangement for a frame element 210a having 9 partial depth openings 248a for the same purpose. When the venting path is formed on the top bonding surface 228, as shown in FIGS. 14A-14C, when the final bonded structure having the frame element is stacked and directly bonded between two other elements to enclose the opening in the frame element, the opening may still be connected to ambient air through the venting path.

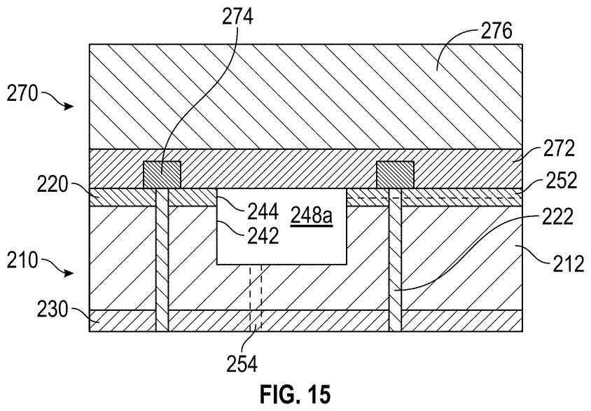

In some embodiments, a vent hole 254 may be formed through the unetched portion under the partial opening 248a of the frame element 210, as shown in FIG. 15. In this case the vent hole 254 may not be present in the final bonded structure since the entire underside of the frame element 210 is to be bonded to and covered by another element (after the opening 248a is etched through the thickness of the frame element 210). Therefore, a hermetic seal can be provided for the cavity formed by the frame element 210, the first element 270 and the second element to be bonded. Such a venting path may be provided in one or more of the frame element 210 and the stacked element(s).

The venting pathways disclosed herein, e.g., the vent groove 252 of FIGS. 14A-15 or the vent hole 254 of FIG. 15, can enable fluid (e.g., moisture and/or air) to be removed from the partial opening 248 in applications in which it is desirable to have the partial opening 248 under vacuum. Moreover, in some embodiments, the vent groove 252 or vent hole 254 can be provided to relieve pressure such that, when the first element 270 is bonded to the frame element 210 and annealed, a pressure differential across the thinned unetched portion of the frame element 210 underlying the partial opening 248 does not cause damage to the frame element 210.

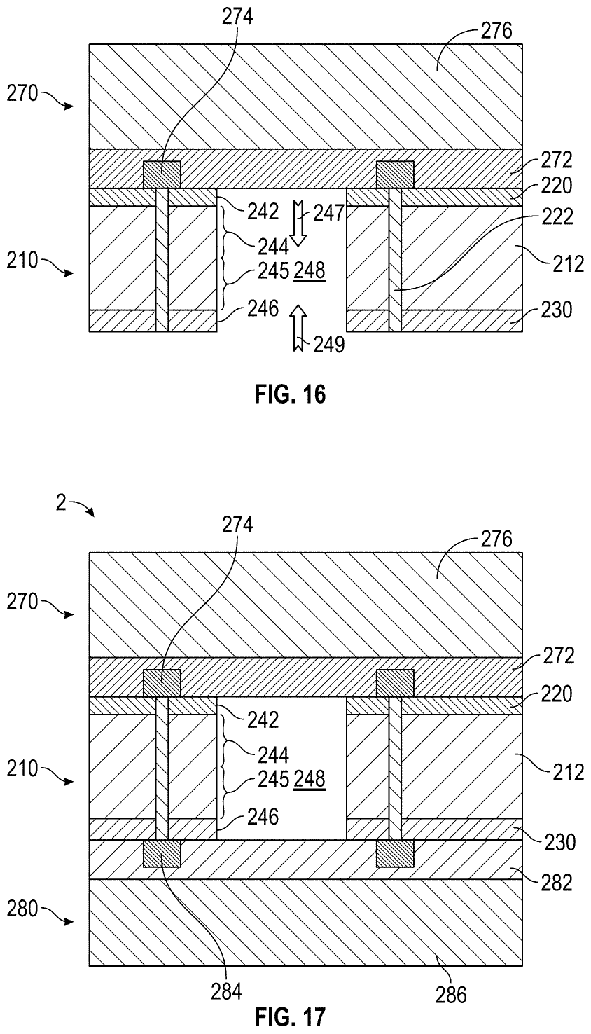

After the frame element 210 is bonded to the first element 270, the frame element 210 can be etched in a second direction 249 from the second bonding surface 238 towards the first element 270, through the second nonconductive layer 230 and remaining thickness of the bulk portion 212, as shown in FIG. 16. As such, an opening 248 through the entire thickness of the frame element 210 is formed, with a third sidewall 246 formed in the second nonconductive layer 236 and a fourth sidewall 245 formed in the lower bulk portion 212. Therefore, the first bonding layer 220 can comprise the second sidewall 244 of the opening 248, having an etch signature indicative of an etch process in the first direction 247. An upper portion of the bulk portion 212 can comprise the first sidewall 242 having an etch signature indicative of an etch process in the first direction 247. On the other hand, the second bonding layer can comprise the third sidewall 246 of the opening 248, having an etch signature indicative of an etch process in the second direction 249. A lower portion of the bulk portion 212 can comprise the fourth sidewall 245 of the opening 248, having an etch signature indicative of an etch process in the second direction 249. The first sidewall 242 and fourth sidewall 245 can meet in the middle somewhere in the interior of bulk portion 212. In some embodiments, there may exist a misalignment for etching from the opposite directions at the junction. This misalignment may create patterns, e.g., offset edges, that form a part of the etch signatures for the first sidewall and the fourth sidewall. In some embodiments when various etching method, e.g., wet etching, is used, the first sidewall 242 and the second sidewall 244 can be tapered in a first orientation, and the third sidewall 246 and the fourth sidewall 245 can be tapered in a opposite second orientation. In some embodiments, the meeting point can project radially inward relative to respective surfaces of the first and fourth sidewalls (for example, due to the opposite tapers).

In FIG. 17, a second element 280 can be directly bonded to the second bonding layer 230 of the frame element 210 over the opening 248 without an intervening adhesive so that the opening 248 is enclosed as an internal cavity 248. As such, a bonded structure 2 is formed to comprise the frame element 210 stacked between the first element 270 and the second element 280 by direct hybrid bonding. The bonded structure 2 in FIG. 17 can be substantially the same as the bonded structure 1 in FIG. 7.

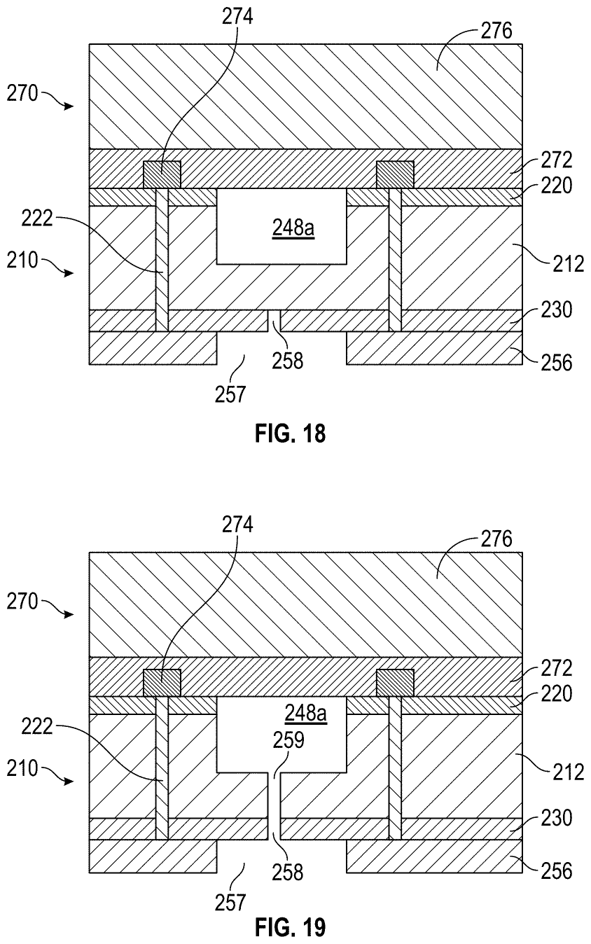

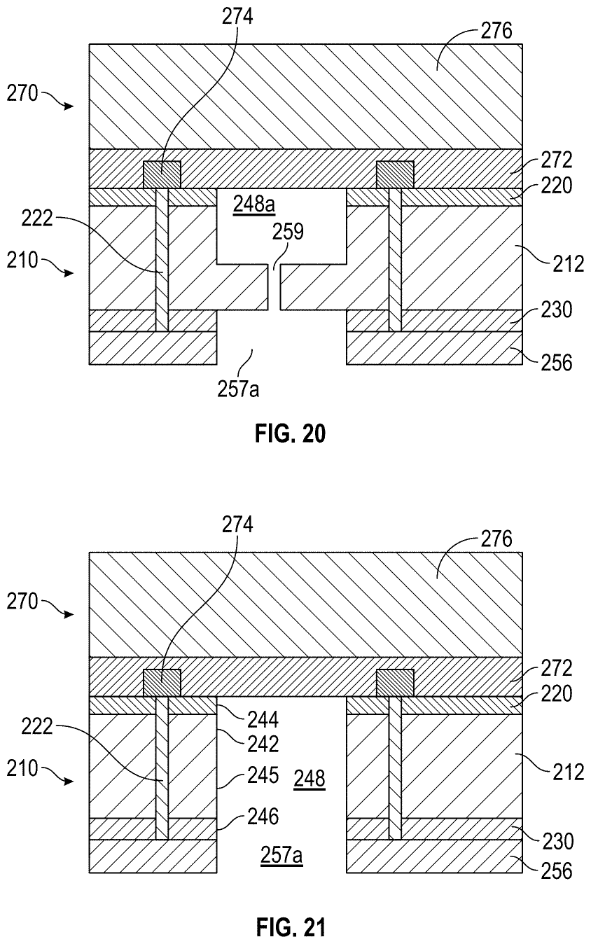

An alternative embodiment for forming a small vent hole 258 in the frame element 210 is illustrated in FIGS. 18-21. In FIG. 18, the process starts from the stage shown in FIG. 13, after the first element 270 is bonded to the frame element 210. The second bonding layer 230 is patterned and etched, forming a small hole 258 in the second nonconductive layer 236. A photoresist layer 256 can be provided over the second bonding layer 230 and patterned to form an opening 257, which is the state shown in FIG. 18. The bulk portion 212 of the frame element 210 can be etched using the second nonconductive layer 236 as the etching mask to form a small hole 259 in the bulk portion 212, as shown in FIG. 19. The small hole 259 in the bulk portion 212 and the small hole 258 in the second nonconductive layer 236 are connected to form a through hole to connect the partial opening 248a to the underside of the frame element 210. In FIG. 20, the second nonconductive layer 230 is etched using the photoresist mask 256 to form an opening 257a, which is an extension of the opening 257 in FIG. 18 and FIG. 19. In FIG. 21, the photoresist mask 256 is used again to etch through the bulk portion 212 of the frame element 210, so that the partial opening 248a is expanded to a larger opening 248 through the entire thickness of the frame element 210 and connected to the opening 257a. Accordingly, when the photoresist layer 256 is removed, and the second element 280 is bonded to the second bonding layer 230 of the frame element 210, the bonded structure 2 in FIG. 17 is formed.

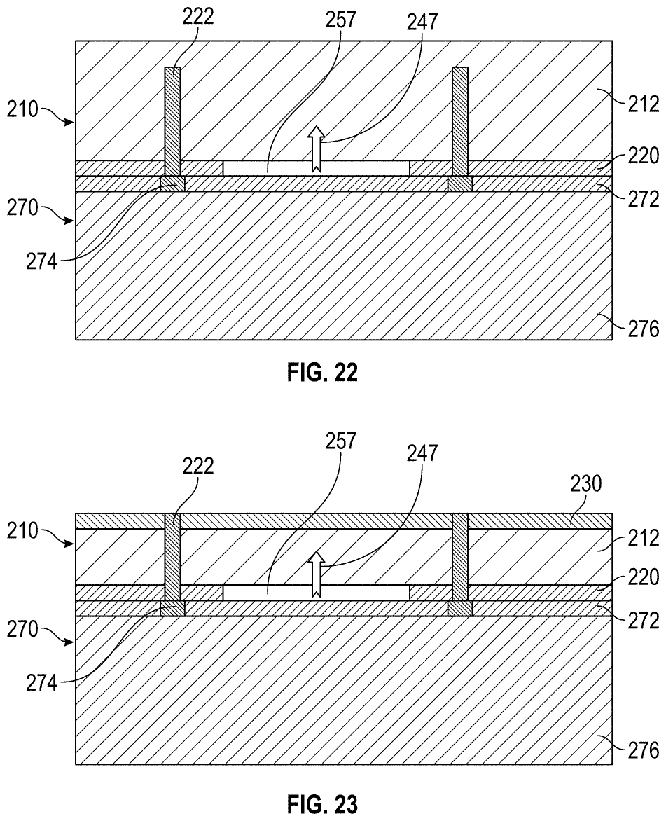

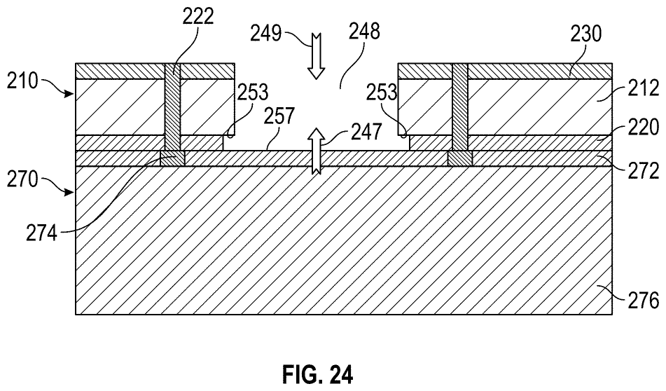

Another alternative embodiment for forming a bonded structure with a frame element without using a temporary support is illustrated in FIGS. 22-24. In FIG. 22, buried TSVs 222 are formed in a frame element 210, through most of the thickness but may not extend through the entire thickness. A first bonding layer 220 is etched in the first direction 247, forming a partial depth opening 257. Then the frame element 210 is directly bonded to a first element 270. In FIG. 23, the top surface of the frame element 210 is thinned to reveal the TSVs 222. A second bonding layer 230 is disposed on a top surface of the bulk portion 212 and conductive contact features which comprise the exposed end of the vias are formed. In FIG. 24, the top surface of the second bonding layer 230 is patterned and the frame element 210 is etched in the second direction 249 to form an opening 248. Due to the etching in opposite directions 247 and 249, there may be misalignment signatures at the interface between the bulk portion 212 and the first bonding layer 220. At this point, the structure in FIG. 24 is at the stage shown in FIG. 16, ready to be bonded to a second element 280.

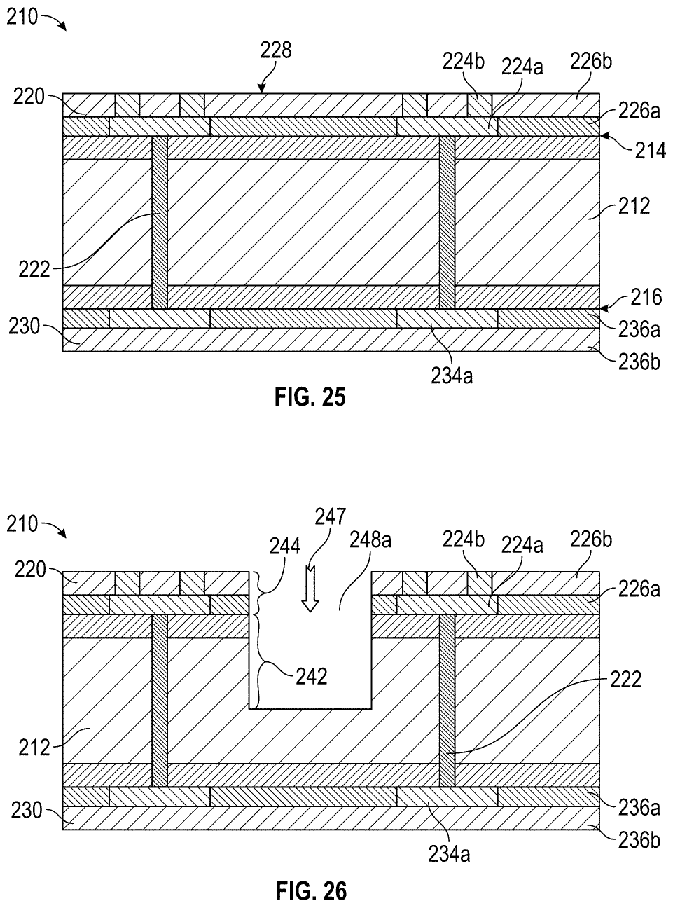

In some embodiments, the bonded structure 1 created following the process steps shown in FIGS. 1-10 and the bonded structure 2 created following the process steps shown in FIGS. 11-24 can have more robust and more reliable direct bonding. This is illustrated by a set of example embodiment process steps shown in FIGS. 25-30, for forming a bonded structure with a cavity in a framed element without a temporary support.

FIG. 25 starts with the frame element 210 in the state of FIG. 11. A nonconductive dielectric layer 226a is disposed on the first surface 214 of the frame 210. Within the nonconductive layer 226a, a metal trace 224a (which may be larger than the size of the through substrate via (TSV)) can be disposed on top of and connected to each TSV. Layers 226a-226b and traces 224a may serve as an RDL. A first nonconductive layer 226b is disposed on the nonconductive layer 226a, and conductive features comprising conductive contact pads 224b are formed in the nonconductive layer 226b. For enhanced direct bonding quality and reliability, more than one contact pads 224b can be formed to connect each RDL conductive traces 224a, creating redundancies. On the second surface 216 of the frame element 210 is disposed a nonconductive layer 236a. As with the top side of frame element 210, a large RDL conductive trace is formed in the nonconductive layer 236a connecting to each TSV. A second bonding layer 236b is disposed on the nonconductive layer 236a. In the illustrated embodiment, the layer 236b may not include conductive contact pads at this stage.

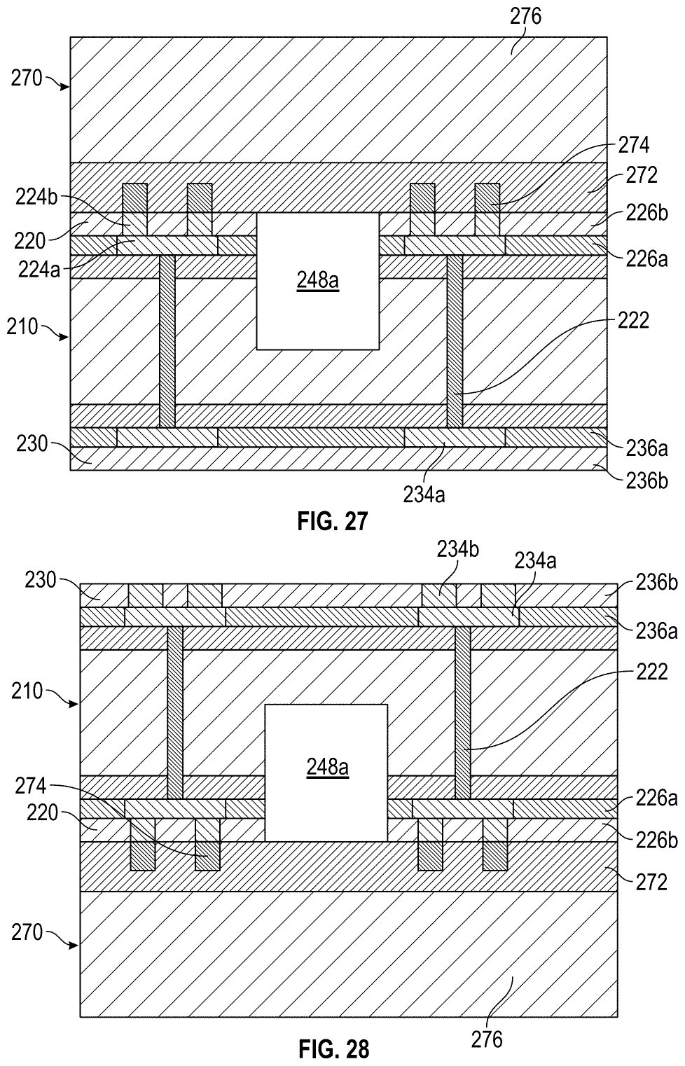

In FIG. 26, as with the process shown in FIG. 12, a first bonding layer 220 is patterned and etched in the first direction 247 to form a partial depth opening 248a in the frame element 210. A first sidewall 242 is formed in the bulk portion 212. A second sidewall 244 is formed in the nonconductive layers 226a and 226b. In FIG. 27, a first frame element 270 is directed bonded to the frame element 210, similar to the process shown in FIG. 13. With redundant conductive pads 224b, which are connected to each TSV in the frame element 210, directly bonded with redundant conductive pads 274 in the first element 270 at the bonding interface, more robust and reliable direct bonding is achieved compared to without redundant conductive pads, e.g., the direct bonding in FIG. 13 and FIG. 5.

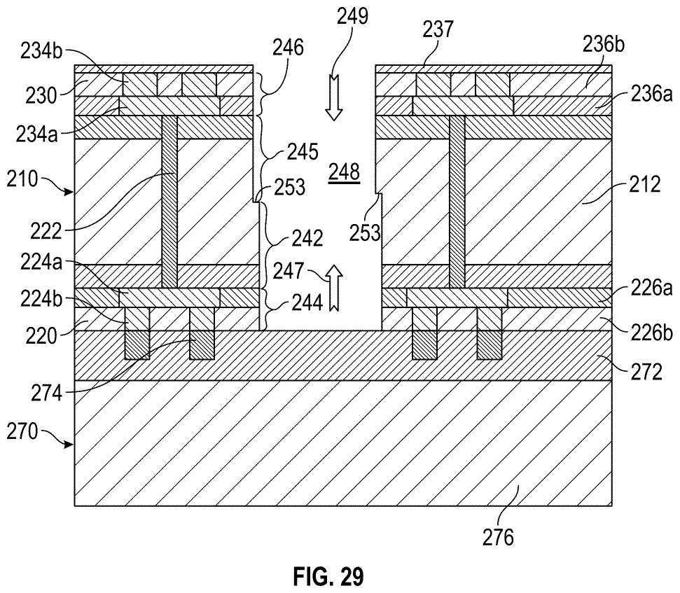

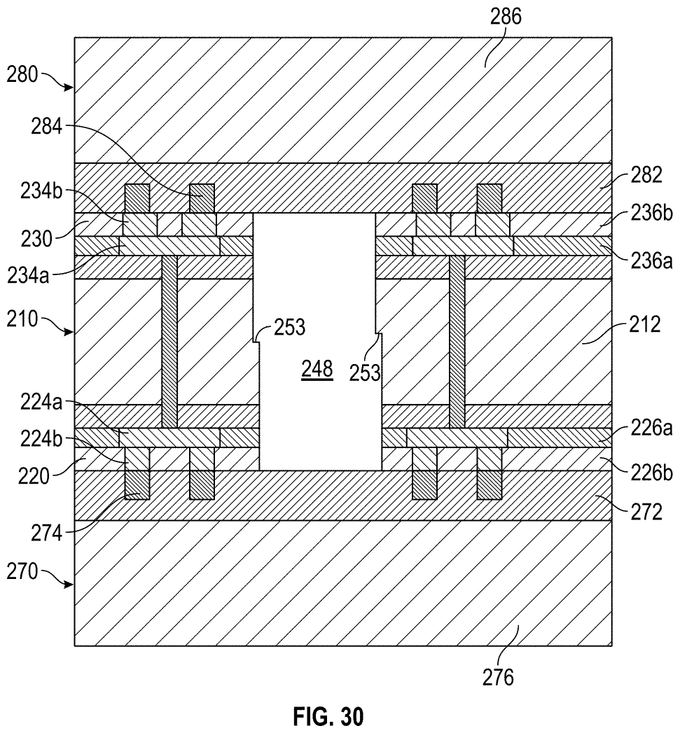

Moving to FIG. 28, the bonded structure is flipped over, and conductive contact pads 234b are formed in the second nonconductive layer 236b. More than one conductive contact pads 234b can be formed on each RDL conductive trace 234a which is connected to respective TSV 222. In FIG. 29, a photoresist layer 237 is formed on the second nonconductive layer 236b and patterned. The top nonconductive layers and the bulk layer 212 of frame element 210 can be etched in the second direction 249 through the remaining partial thickness to form an opening 248, which is through the entire thickness of the frame element 210. The etching process is similar to the process shown in FIG. 16. A third sidewall 246 can be formed in the second nonconductive layer 236b and a fourth sidewall 245 can be formed in the partial bulk portion 212. As with the opening 248 in FIG. 16, in FIG. 29, the second sidewall 244 in the first nonconductive layer 226b, the first sidewall 242 in the lower part of the bulk portion 212, the fourth sidewall 245 in the upper bulk portion 212, and the third sidewall 246 in the second nonconductive layer 236b may each have unique etch signatures indicative of etch process conditions, including etching direction, the material being etched and the etching method. The etching in the first direction 247 and the subsequent etching in the second direction 249 may meet at a junction in a vertically-interior region of the opening 248. In some embodiments, there may exist misalignment for etching from the opposite directions at the junction, illustrated as the misalignment edges 253 shown in FIG. 29. This misalignment may create patterns, that make part of etch signatures for the first sidewall 244 and the fourth sidewall 245. In FIG. 30, the photoresist layer 237 is removed, and a second element 280 is directly bonded to the frame element 210 at the second bonding layer 230, so that the cavity 248 is enclosed by the elements. As with the direct bonding in FIG. 27, the direct bonding of the redundant contact pads 284 in the second element 280 to the corresponding contact pads 234b in the frame element 210 substantially enhances the bonding quality and reliability.

Another set of example embodiment process steps for forming a bonded structure a framed element are illustrated in FIGS. 31-35. A frame element 310 shown in FIG. 31 comprises substantially similar or the same structures as the frame element 110 in FIG. 1 and the frame element in FIG. 12. The reference numerals in FIG. 31 for structural elements of the frame element 310 are incremented by 100 from the reference numerals for the frame element 210 in FIG. 11. As such, descriptions for the frame element 110 and the frame element 210 can be applied to the frame element 310 in FIG. 31.

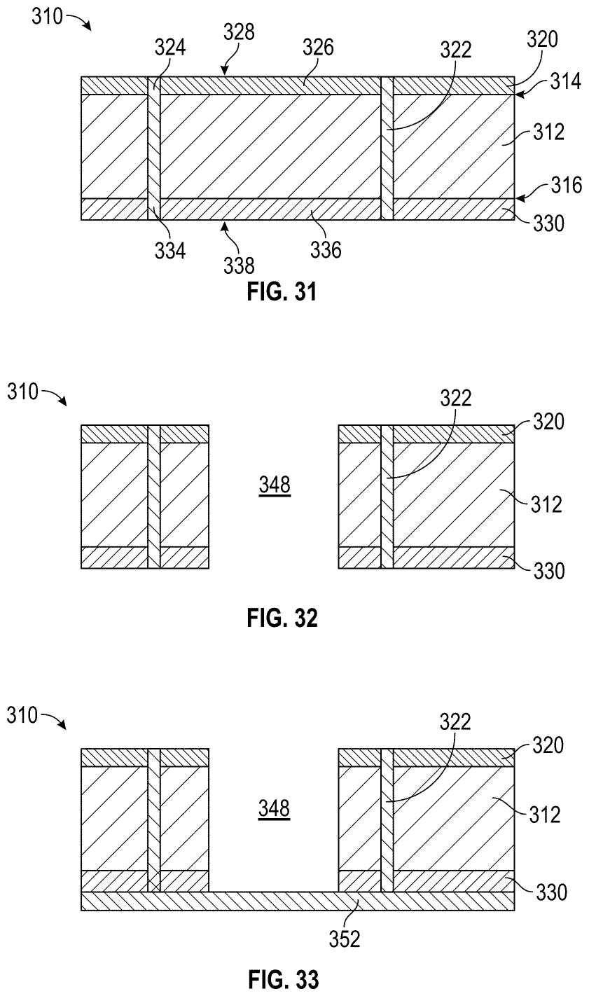

In FIG. 32, the frame element 310 is etched to form an opening 348 through the entire thickness. Selective etchings may be performed for each of the layers, the first bonding layer 320, the bulk portion 312, and the second bonding layer 330. In other embodiments an etching method can be used to etch through all layers in one step. In FIG. 33, instead of using a temporarily bonded support 160 as shown in FIGS. 2-4, a support tape 352 can be applied to the second bonding layer 330 to support the frame element 310. The tape 352 can be applied either with a tape frame or without a tape frame.

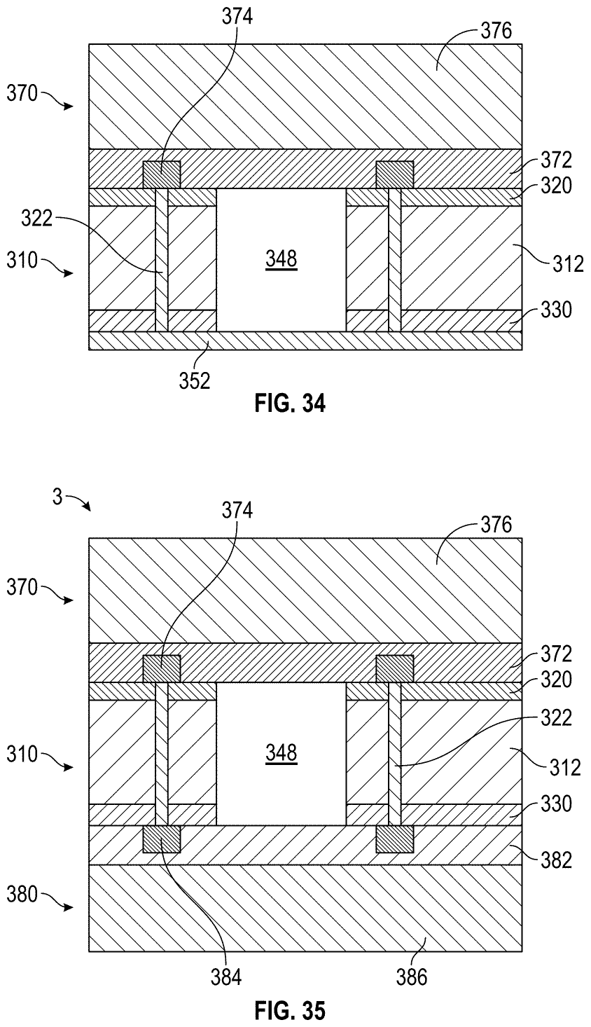

Referring to FIG. 34, a first element 370 is directly bonded to the frame element 310, following the bonding process described with FIG. 5. Then, the support tape 352 is peeled off or otherwise removed, and a second element 380 is bonded to the second bonding layer 330 of the frame element 310 to form a bonded structure 3, as shown in FIG. 35. As such, a cavity 348, which is from the opening 348, is enclosed by the frame element 310, the first element 370 and the second element 380. The bonded structure 3 in FIG. 35 is the same as or generally similar to the bonded structure 1 in FIG. 7 and the bonded structure 2 in FIG. 17.

As disclosed herein, in order to achieve successful direct bonding of a frame element with opening to another element, the frame element can be temporarily bonded to a rigid support, as shown in FIG. 5. Or the frame element may only be partially etched to ensure that it is structurally strong enough to undergo the direct bonding process, as shown in FIG. 13. In some embodiments a tape can be applied to support the frame element with an opening for direct bonding, as shown in FIG. 34. However, other embodiments are disclosed herein to support the framed element with a through-thickness opening to facilitate direct bonding. In some embodiments, a low bond chuck is used to hold the frame element for ease of handling. The low bond chuck may have tiny holes formed on a top holding surface and connected to a vacuum source. When the frame element is placed on the top holding surface of the low bond chuck, a vacuum source is turned on and the frame element is held tightly onto the low bond chuck and supported. In this way, direct bonding of the frame element to a first element is performed when the frame element is reinforced.

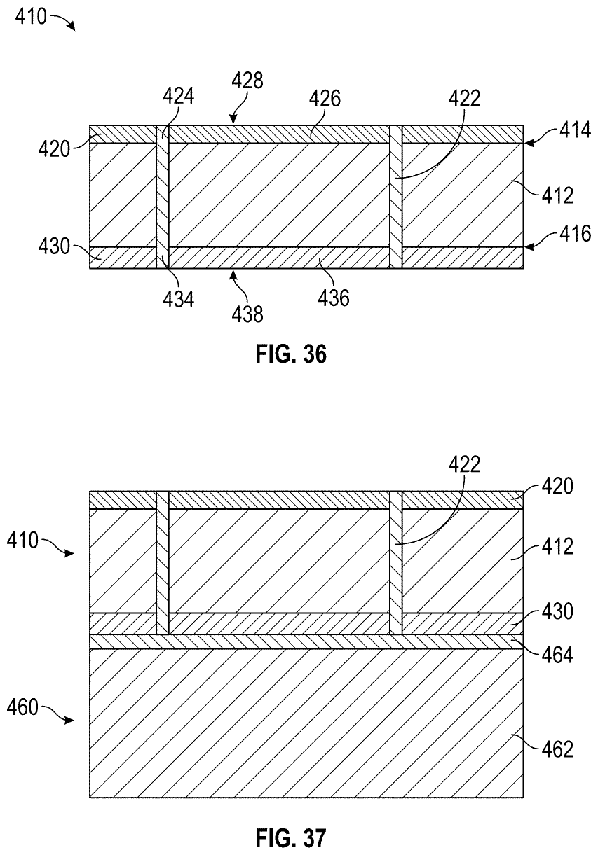

Yet another set of example embodiment process steps for forming a bonded structure a framed element is illustrated in FIGS. 36-41. These process steps may be generally similar to the example process steps illustrated in FIG. 1-7, except that the frame element is mounted to a support comprising a substrate having an inorganic bonding layer for temporary direct bonding. In FIG. 36, a frame element 410 in cross-sectional view is substantially the same as the frame element 110 shown in FIG. 1, the frame element 210 in FIG. 11, and/or the frame element 310 in FIG. 31, except that reference numerals are incremented to the 400s. Therefore, the same structural and functional descriptions for frame element 110 can be applied to frame element 410.

In FIG. 37, the frame element 410 is directly bonded to a temporary support 460 having a support substrate 462 made of a material sufficiently strong to support the frame element 410 (e.g., rigid), e.g., a silicon, a glass, a ceramic, or a metal, and including a temporary bonding layer 464 on the bulk portion 412. The temporary bonding layer 464 may comprise a silicon nitride material or another type of inorganic dielectric material. The selected dielectric bonding material may demonstrate weak bonding surface energy, e.g., in the range of 100-1000 μJ/m². Other optional materials to create a weak nonconductive direct bond may include an oxide with high impurity content that can volatilize at certain conditions to weaken bonding, a chemical modification applied to the bonding surface on one or both sides to reduce bonding strength, and other dielectric material that can form a relatively weak direct bond. The bonding layer 464 of the support 460 may be prepared and planarized using nonconductive direct bonding processes. Part of the bonding surface on the bonding layer 464 may be patterned and etched to form recessed areas so that the bonding area is reduced. Then the temporary bonding layer 464 of the support 460 is directly bonded to the second bonding layer 430 of the frame element 410 and annealed. The weak bonding dielectric material, e.g., silicon nitride, together with the reduced bonding area makes the bonding strength at the bonding interface relatively low and easy to be de-bonded.

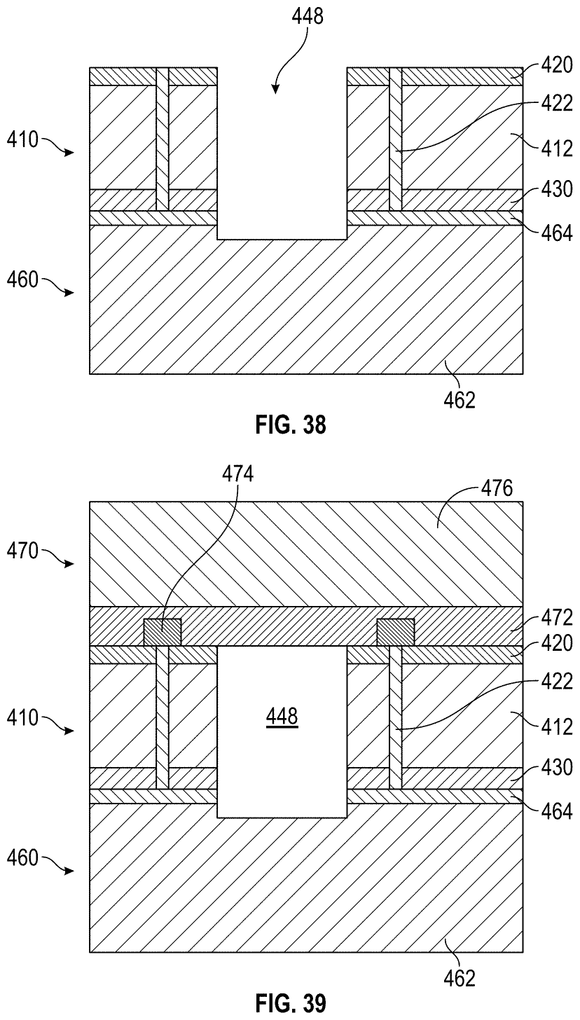

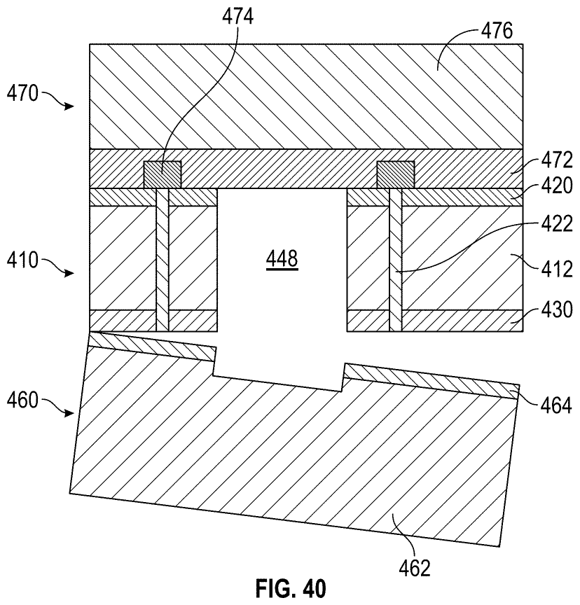

In FIG. 38, reinforced by the temporary support 460, the frame element is patterned and etched to form an opening 448 through the entire thickness, following substantially similar process steps as shown in FIG. 3, FIG. 4A and FIG. 4B for the frame element 110. In FIG. 39, the frame element 410 is directly bonded to a first element 470, following the process described with respect to FIG. 5. The first element 470 may comprise a device layer 476 that may include a metallization layer embedded therein. As shown in FIG. 40, the temporary support 460 is mechanically remove by debonding the temporary bonding layer 474 of the support 460 from the second bonding layer 430 of the frame element 410. The debonding step may be done by simply pulling the support 460 from a corner or a side, using a tape or a vacuum, or a combination of both. After debonding, the second bonding surface 338 of the frame element 410 may be wet cleaned or prepared by a touch chemical mechanical polish (CMP) so that it is prepared for direct bonding again.

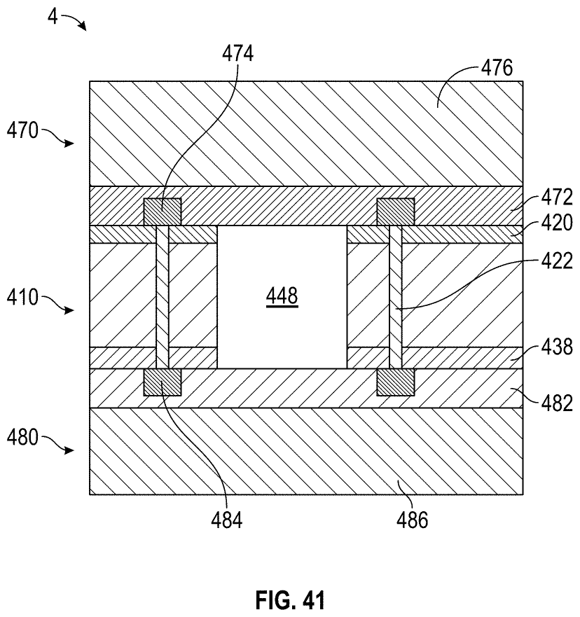

In FIG. 41, a second element 480 is bonded to the second bonding layer 430 of the frame element 410 to form a bonded structure 4, with the cavity 348 enclosed in the middle. The bonded structure 4 in FIG. 41 may be similar to or the same as the bonded structure 1 in FIG. 7, the bonded structure 2 in FIG. 17, and/or the bonded structure 3 in FIG. 35. Various differences between the illustrated bonded structures may be produced due to different processes used to form the bonded structures.

It is to be noted that if a temporary support is used, including the temporary support 160 in the first set of process steps, the temporary support 460 in the last process steps described above, and the tape 352, after debonding or tape removal the cavity in the frame element may be chemically cleaned to remove debris, e.g., remaining organic or inorganic material, e.g., silicon nitride. A selective chemical cleaning to the debris may not adversely change the topography of the dielectric material layer and the conductive contact pad. Furthermore, a touch-up chemical mechanical polish (CMP) may be used to remove the debris and restore the topography for the frame wafer that was bonded to a tape, temporary bond material or silicon nitride.

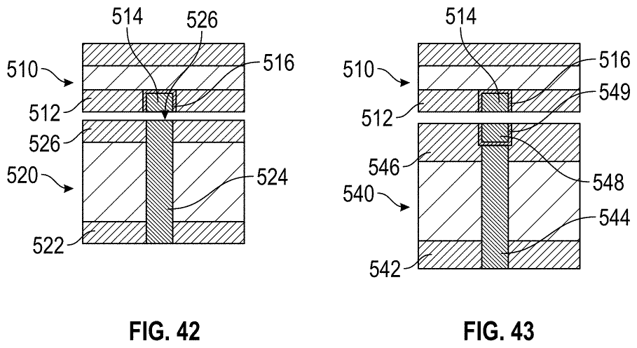

The different processes disclosed above include different arrangements for TSVs in the frame elements and contact pads in the bonding layers. For example, FIGS. 25-30 show redundant contact pads. The contact pads embedded in the bonding layers can be formed of any suitable conductive material, for example, a metal such as copper, nickel, or aluminum. The material selection for TSVs may affect a choice for how the contact pads are formed. FIGS. 42-48 provide a few example embodiments for various contact pad and TSV implementations.

In each of FIGS. 42-45 is shown a cross-sectional view of a device element 510 above a frame element 520, 540, 560 or 580 prepared to be directly bonded to one another. The device element 510 in the figures have the same substrate portion and bonding layer structures as described herein. The frame elements 520, 540, 560 and 580 can share the same bulk portion and bonding layer structure except the TSV and contact pads. Therefore, descriptions for FIG. 42 for the basic element structures including bonding layers can be applied to FIGS. 43-45.

In FIG. 42, a frame element 520 is illustrated below a semiconductor element 521 separated by a space before direct bonding, e.g., the frame element 520 and the semiconductor element 510 are in the state ready to be directly bonded. The frame element comprises an upper bonding layer 526 and a lower bonding layer 522, with a TSV 524 extending through its thickness. The top surface of the upper bonding layer 526 is planarized so that the TSV is exposed and prepared for direct bonding. In the device element 510 a contact pad 514 is formed in a bonding layer 512. Before the contact pad is formed, a thin barrier layer 516 can be deposited on the walls of a cavity for the contact pad to prevent diffusion of the contact pad material into the surrounding dielectric material. Another thin seeding layer may be deposited on top of the barrier layer 516 to facilitate electroplating the contact pad 514. Therefore, in the case of FIG. 42, when the frame element 520 is bonded to the semiconductor element 510, the upper bonding layer 526 of the frame element 520 is directly bonded to the bonding layer 512 of the semiconductor element 510. The exposed surface 526 of the TSV 524 is directly bonded to the contact pad 514. The TSV in the frame element 520 and the contact pad 514 in the semiconductor element 510 may comprise the same material, e.g., copper, in various embodiments.

In FIG. 43, a frame element 540 comprises an upper bonding layer 546 and the lower bonding layer 542 that may be generally similar to the bonding layers in the frame element 520 in FIG. 42. A TSV extends through the thickness of the frame element 520 from the bottom surface of the lower bonding layer 542 to connect to a conductive contact pad 548. Similar to the contact pad 514 in the semiconductor element 510, before the contact pad 548 is formed in the upper bonding layer 526, a thin barrier layer 549 can be deposited on the walls of a cavity formed for the contact pad 548 to prevent diffusion of the contact pad material into the surrounding dielectric material. In the case of FIG. 43, the direct bonding between conductive features in the frame element 540 and the semiconductor element 510 comprises a contact pad-to-contact pad connection, as opposed to the via-to-contact pad connection of FIG. 42. One advantage of using a contact pad for direct bonding is that it can be made to cover a larger bonding area for better bonding quality and reliability. The TSV in the frame element 540, the contact pad in the upper bonding layer 546 of the frame element 540, and the contact pad 514 in the semiconductor element 510 may comprise the same material, e.g., copper, in some embodiments.

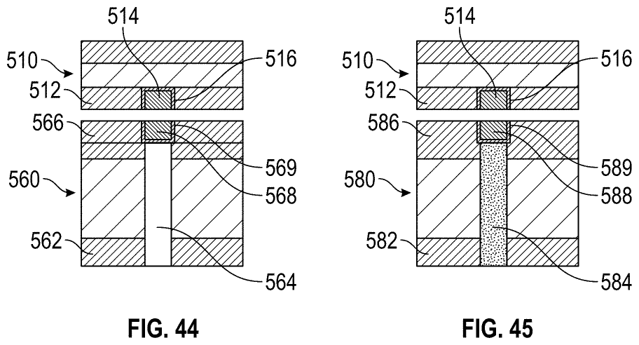

In FIG. 44, a TSV 564 and a contact pad 568 in an upper bonding layer 556 of a frame element 560 may be generally similar to the TSV 544 and contact pad 348 in FIG. 43, except that the TSV 654 and the contact pad 568 comprise different materials. For example, the TSV 654 may be made of tungsten and the contact pad 568 may be made of copper. A thin barrier layer 569 is deposited on the walls of a cavity formed for the contact pad 568 to prevent diffusion of the contact pad material into the surrounding dielectric material. Furthermore, in FIG. 45, a TSV 584 may be made of polysilicon, to connect to a contact pad 588 that may be made of copper. The contact pad 588 is surrounded by a thin barrier layer 589 and embedded in an upper bonding layer 586.

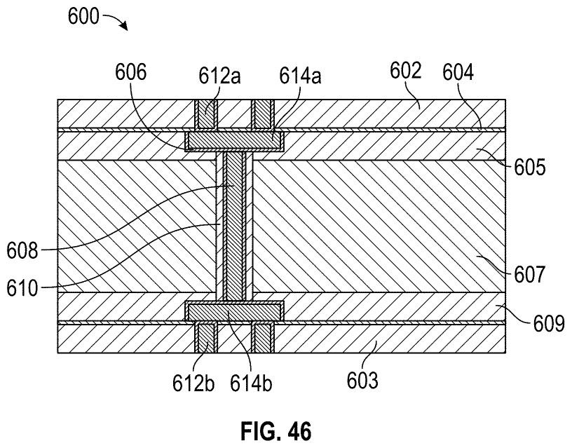

A frame element with redundant contact pads are shown in FIGS. 25-30. In FIGS. 46-48, example embodiments of frame elements with redundant contact pads in cross-sectional views are illustrated. In FIG. 46, a frame element 600 comprises a bulk portion 607, a first dielectric bonding layer 602 having first redundant contact pads 612a embedded therein, and a second bonding layer 603 having second redundant contact pads 612b embedded therein. The first redundant contact pads 612a connect to a first RDL conductive trace 614a in dielectric layer 605. The dielectric material of the first bonding layer 602 and the dielectric layer 605 may comprise any suitable dielectric layer, e.g., silicon oxide, silicon nitride, or silicon oxynitride. A thin layer of silicon nitride 604 may separate the first bonding layer 602 and the underlying dielectric layer 605. On the bottom side of the frame element 600, the second bonding layer 603 with embedded redundant contact pads 612b, an underlying dielectric layer 609 with a second RDL conductive trace 614b buried therein, and a thin layer of silicon nitride between the dielectric layers may be generally similar to the respective structure on the top side. In the bulk portion 607 of the frame element 600, a TSV 608 extends through and connects to the first RDL conductive trace 614a above and to the second RDL conductive feature 614b below. The conductive traces, including the first contact pads 612a, the first RDL conductive trace 614a, the TSV 608, the second TSV trace 614b, and the second contact pads 612b may be made of the same material, e.g., copper, nickel, tungsten, aluminum, or polysilicon, or of different materials. A barrier layer 606 may be deposited surrounding each of the contact pad, RDL conductive trace, and TSV feature. In the bulk portion 607, a layer of liner oxide 610 is formed surrounding the TSV 608 outside the barrier layer.

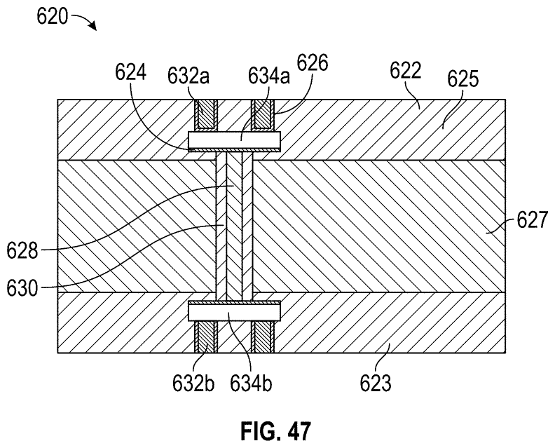

In FIG. 47, a frame element 620 comprises a bulk portion 627, a first dielectric bonding layer 622 having first redundant contact pads 632a embedded therein, and a second bonding layer 623 having second redundant contact pads 632b embedded therein. Similar to the frame element 610 in FIG. 46, a TSV 628 extends through the bulk portion 627 connecting to a first RDL conductive trace 634a above and to a second RDL conductive trace 634b below. The difference between FIG. 47 and FIG. 46 is that the conductive materials for the pads, traces, and TSVs may be different conductors, e.g., copper, tungsten, nickel, aluminum, other metals, polysilicon, etc. For example, the first contact pads 632a and the second contact pads 632b may be made of copper surrounded by a thin layer of copper barrier material. The first RDL conductive trace 632a and the second RDL conductive trace 632b may be made of aluminum in some embodiments. The TSV 628 may be made of polysilicon or tungsten. A thin layer of conductive material such as titanium or titanium nitride may be provided between the TSV 638 and the first RDL conductive trace 632a or the second RDL conductive trace 632b. As with FIG. 46, the liner oxide layer 630 can be formed to surround the TSV 628. In some embodiments the oxide material for the liner oxide layer 630 is selected to be compatible with the polysilicon or tungsten material used for the TSV 628.

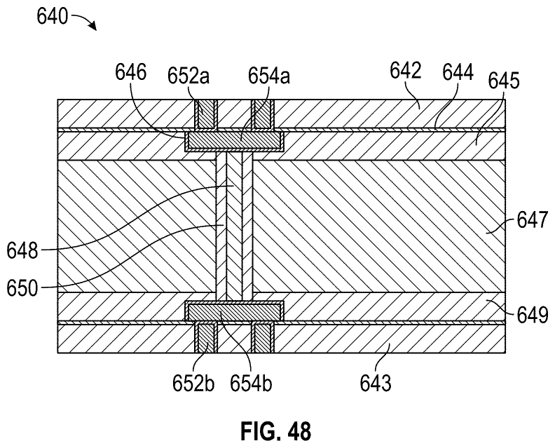

Another embodiment is illustrated in FIG. 48, with the same structures in FIG. 46, except that a TSV 648 may be made of polysilicon or tungsten with a liner oxide layer formed surrounding it. Therefore, first redundant contact pads in a first bonding layer 642 connect to an underlying first RDL conductive trace 654a, which in turn connects to the TSV 648, which in turn connects to a second RDL conductive trace 654b, which in turn connects to second redundant contacts 654b in a second bonding layer 643. The first and second contact pads 652a and 652b and the first and second RDL conductive trace 654a and 654b may be made of copper.

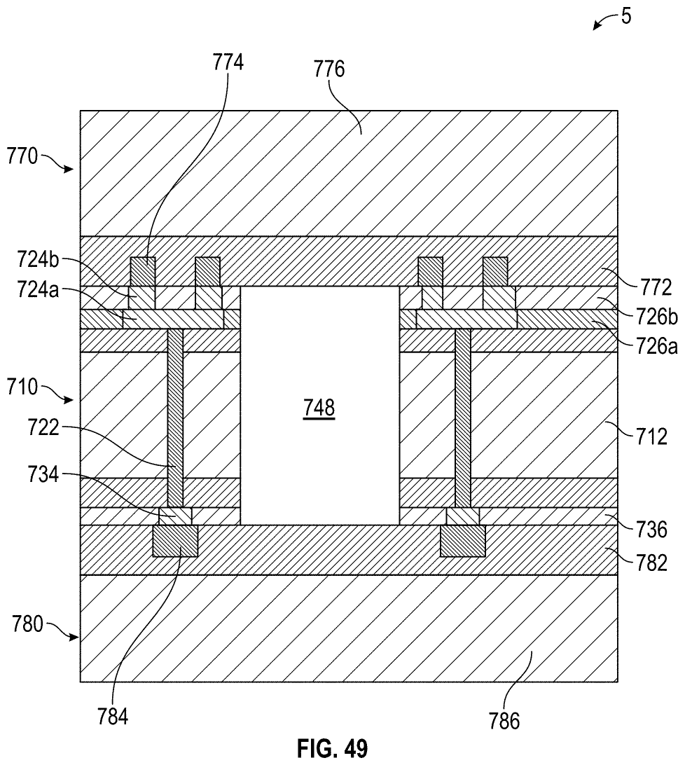

A cross-sectional view of a bonded structure 5 is illustrated in FIG. 49 and may include the structures disclosed with FIGS. 42-48. The structure of the bonded structure in FIG. 49 may be similar to the bonded structure shown in FIG. 30, except that a second element 780 may not comprise redundant contact pads. In FIG. 49, the bonded structure 5 comprises a frame element 710 directed bonded to a first element 770 above and to a second element 780 below, enclosing a cavity 748 formed across the thickness of the frame element 710. The frame element 710 comprises at least one TSV 722 through its thickness and connecting to a first conductive trace 724b in a dielectric layer 726a above and connecting to a conductive contact pad 734 embedded in a second bonding layer 736. The dielectric layer 726a and the conductive trace 724b may serve as RDL. Each contact pad 734 is directly bonded to a contact pad 784 embedded in a bonding layer 782 disposed on a device layer 786 of the second element 780.

On the top side of the frame element 710, the first bonding layer 726b has redundant contact pads 724b embedded therein making connection with the underlying first conductive trace 724a. The redundant contact pads 724b are directed bonded to the redundant contact pads 774 embedded in the bonding layer 772 which is disposed on a device layer 776 of the first element 770.

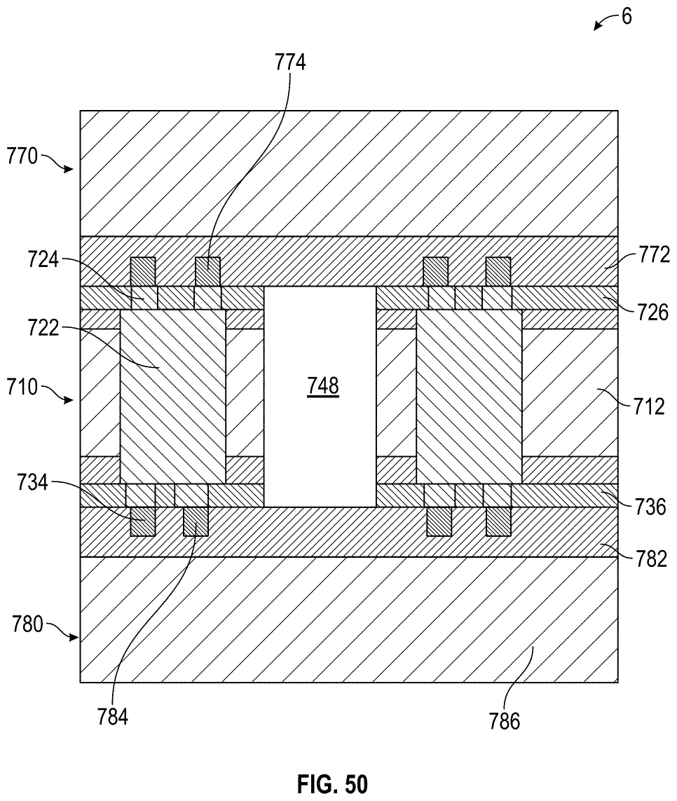

FIG. 50 shows an embodiment of a bonded structure 6 comprising frame elements similar to those in FIG. 49, having redundant contact pads on both the top side and on the bottom side. Unlike the embodiment of FIG. 49, the TSVs 722 in FIG. 50 are formed with width larger than the width of the contact pads 774 and 784. As such, more than one contact pad 774 or 784 can be formed in a bonding layer to connect to each underlying TSV 722. For example, the first redundant TSVs 724 are formed in the first bonding layer 726 to connect to each TSV 722 from above. The second redundant TSVs 734 are formed in the second bonding layer 736 to connect to each TSV 722 from below. The redundant contact pads ensures better direct bonding quality and reliability. In other embodiments, the width of TSV can be smaller than the corresponding contact. This may lead to the implementation in FIG. 49, where a conductive trace 724b or 734b may connect a TSV 722 to redundant contact pads 774 or 784.

### Examples of Direct Bonding Methods and Directly Bonded Structures

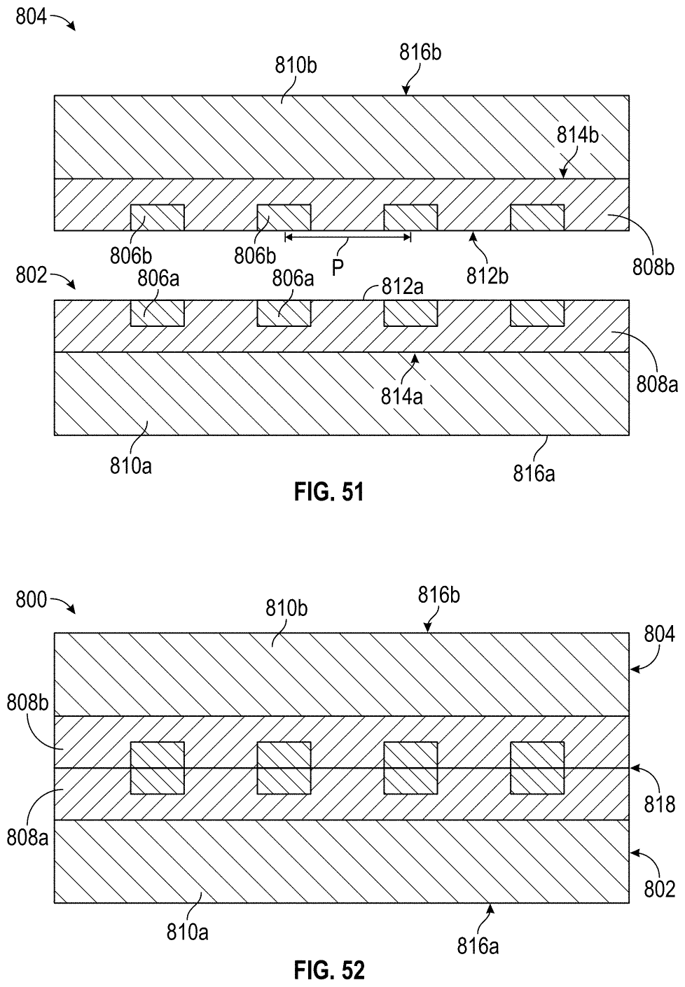

Various embodiments disclosed herein relate to directly bonded structures in which two elements can be directly bonded to one another without an intervening adhesive. FIGS. 51 and 52 schematically illustrate a process for forming a directly hybrid bonded structure without an intervening adhesive according to some embodiments. In FIGS. 51 and 52, a bonded structure 800 comprises two elements 802 and 804 that can be directly bonded to one another at a bond interface 818 without an intervening adhesive. Two or more microelectronic elements 802 and 804 (such as semiconductor elements, including, for example, integrated device dies, wafers, passive devices, individual active devices such as power switches, etc.) may be stacked on or bonded to one another to form the bonded structure 800. Conductive features 806a (e.g., contact pads, exposed ends of vias (e.g., TSVs), or a through substrate electrodes) of the first element 802 may be electrically connected to corresponding conductive features 806b of the second element 804. Any suitable number of elements can be stacked in the bonded structure 800. For example, a third element (not shown) can be stacked on the second element 804, a fourth element (not shown) can be stacked on the third element, and so forth. Additionally, or alternatively, one or more additional elements (not shown) can be stacked laterally adjacent one another along the first element 802. In some embodiments, the laterally stacked additional element may be smaller than the second element. In some embodiments, the laterally stacked additional element may be two times smaller than the second element.

In some embodiments, the elements 802 and 804 are directly bonded to one another without an adhesive. In various embodiments, a non-conductive field region that includes a non-conductive or dielectric material can serve as a first bonding layer 808a of the first element 802 which can be directly bonded to a corresponding non-conductive field region that includes a non-conductive or dielectric material serving as a second bonding layer 808b of the second element 804 without an adhesive. The non-conductive bonding layers 808a and 808b can be disposed on respective front sides 814a and 814b of device portions 810a and 810b, such as a semiconductor (e.g., silicon) portion of the elements 802 and 804. Active devices and/or circuitry can be patterned and/or otherwise disposed at or near the front sides 814a and 814b of the device portions 810a and 810b, and/or at or near opposite backsides 816a and 816b of the device portions 810a and 810b. Bonding layers can be provided on front sides and/or back sides of the elements. The non-conductive material can be referred to as a non-conductive bonding region or bonding layer 808a of the first element 802. In some embodiments, the non-conductive bonding layer 808a of the first element 802 can be directly bonded to the corresponding non-conductive bonding layer 808b of the second element 804 using dielectric-to-dielectric bonding techniques. For example, non-conductive-to-non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 808a and/or 808b can comprise a non-conductive material such as a dielectric material, e.g., silicon oxide, or an undoped semiconductor material, e.g., undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials do not comprise polymer materials, such as epoxy, resin or molding materials.

In some embodiments, the device portions 810a and 810b can have a significantly different coefficients of thermal expansion (CTEs) defining a heterogenous structure. The CTE difference between the device portions 810a and 810b, and particularly between bulk semiconductor, typically single crystal portions of the device portions 810a, 810b, can be greater than 5 ppm or greater than 10 ppm. For example, the CTE difference between the device portions 810a and 810b can be in a range of 5 ppm to 100 ppm, 5 ppm to 40 ppm, 10 ppm to 100 ppm, or 10 ppm to 40 ppm. In some embodiments, one of the device portions 810a and 810b can comprise optoelectronic single crystal materials, including perovskite materials, that are useful for optical piezoelectric or pyroelectric applications, and the other of the device portions 810a, 810b can comprise a more conventional substrate material. For example, one of the device portions 810a, 810b comprises lithium tantalate (LiTaO3) or lithium niobate (LiNbO3), and the other one of the device portions 810a, 810b comprises silicon (Si), quartz, fused silica glass, sapphire, or a glass. In other embodiments, one of the device portions 810a and 810b comprises a III-V single semiconductor material, such as gallium arsenide (GaAs) or gallium nitride (GaN), and the other one of the device portions 810a and 810b can comprise a non-III-V semiconductor material, such as silicon (Si), or can comprise other materials with similar CTE, such as quartz, fused silica glass, sapphire, or a glass.

In various embodiments, direct hybrid bonds can be formed without an intervening adhesive. For example, nonconductive bonding surfaces 812a and 812b can be polished to a high degree of smoothness. The nonconductive bonding surfaces 812a and 812b can be polished using, for example, chemical mechanical polishing (CMP). The roughness of the polished bonding surfaces 812a and 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. The bonding surfaces 812a and 812b can be cleaned and exposed to a plasma and/or etchants to activate the surfaces 812a and 812b. In some embodiments, the surfaces 812a and 812b can be terminated with a species after activation or during activation (e.g., during the plasma and/or etch processes). Without being limited by theory, in some embodiments, the activation process can be performed to break chemical bonds at the bonding surfaces 812a and 812b, and the termination process can provide additional chemical species at the bonding surfaces 812a and 812b that improves the bonding energy during direct bonding. In some embodiments, the activation and termination are provided in the same step, e.g., a plasma to activate and terminate the surfaces 812a and 812b. In other embodiments, the bonding surfaces 812a and 812b can be terminated in a separate treatment to provide additional species for direct bonding. In various embodiments, the terminating species can comprise nitrogen. For example, in some embodiments, the bonding surface(s) 812a, 812b can be exposed to a nitrogen-containing plasma. Further, in some embodiments, the bonding surfaces 812a and 812b can be exposed to fluorine. For example, there may be one or multiple fluorine peaks at or near a bond interface 818 between the first and second elements 802, 804. Thus, in the directly bonded structure 800, the bond interface 818 between two non-conductive materials (e.g., the bonding layers 808a and 808b) can comprise a very smooth interface with higher nitrogen content and/or fluorine peaks at the bond interface 818. Additional examples of activation and/or termination treatments may be found int U.S. Pat. Nos. 9,564,414; 9,391,143; and 10,434,749, the entire contents of each of which are incorporated by reference herein in their entirety and for all purposes. The roughness of the polished bonding surfaces 812a and 812b can be slightly rougher (e.g., about 1 Å rms to 30 Å rms, 3 Å rms to 20 Å rms, or possibly rougher) after an activation process.

In various embodiments, conductive features 806a of the first element 802 can also be directly bonded to corresponding conductive features 806b of the second element 804. For example, a direct hybrid bonding technique can be used to provide conductor-to-conductor direct bonds along the bond interface 818 that includes covalently direct bonded non-conductive-to-non-conductive (e.g., dielectric-to-dielectric) surfaces, prepared as described above. In various embodiments, the conductor-to-conductor (e.g., conductive feature 806a to conductive feature 806b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In direct hybrid bonding embodiments described herein, conductive features are provided within non-conductive bonding layers, and both conductive and nonconductive features are prepared for direct bonding, such as by the planarization, activation and/or termination treatments described above. Thus, the bonding surface prepared for direct bonding includes both conductive and non-conductive features.

For example, non-conductive (e.g., dielectric) bonding surfaces 812a, 812b (for example, inorganic dielectric surfaces) can be prepared and directly bonded to one another without an intervening adhesive as explained above. Conductive contact features (e.g., conductive features 806a and 806b which may be at least partially surrounded by non-conductive dielectric field regions within the bonding layers 808a, 808b) may also directly bonded to one another without an intervening adhesive. In various embodiments, the conductive features 806a, 806b can comprise discrete pads or traces at least partially embedded in the non-conductive field regions. In some embodiments, the conductive contact features can comprise exposed contact surfaces of through substrate vias (e.g., through silicon vias (TSVs)). In some embodiments, the respective conductive features 806a and 806b can be recessed below exterior (e.g., upper) surfaces (non-conductive bonding surfaces 812a and 812b) of the dielectric field region or non-conductive bonding layers 808a and 808b, for example, recessed by less than 30 nm, less than 20 nm, less than 15 nm, or less than 10 nm, for example, recessed in a range of 2 nm to 20 nm, or in a range of 4 nm to 10 nm. In various embodiments, prior to direct bonding, the recesses in the opposing elements can be sized such that the total gap between opposing contact pads is less than 15 nm, or less than 10 nm. The non-conductive bonding layers 108a and 108b can be directly bonded to one another without an adhesive at room temperature in some embodiments and, subsequently, the bonded structure 100 can be annealed. Upon annealing, the conductive features 106a and 106b can expand and contact one another to form a metal-to-metal direct bond. Beneficially, the use of Direct Bond Interconnect, or DBI®, techniques commercially available from Adeia of San Jose, Calif., can enable high density of conductive features 806a and 806b to be connected across the direct bond interface 818 (e.g., small or fine pitches for regular arrays). In some embodiments, the pitch, P, of the conductive features 806a and 806b, such as conductive traces embedded in the bonding surface of one of the bonded elements, may be less than 100 microns or less than 10 microns or even less than 2 microns. For some applications, the ratio of the pitch of the conductive features 806a and 806b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various embodiments, the conductive features 806a and 806b and/or traces can comprise copper or copper alloys, although other metals may be suitable. For example, the conductive features disclosed herein, such as the conductive features 806a and 806b, can comprise fine-grain metal (e.g., a fine-grain copper).

Thus, in direct bonding processes, a first element 802 can be directly bonded to a second element 804 without an intervening adhesive. In some arrangements, the first element 802 can comprise a singulated element, such as a singulated integrated device die. In other arrangements, the first element 802 can comprise a carrier or substrate (e.g., a wafer) that includes a plurality (e.g., tens, hundreds, or more) of device regions that, when singulated, form a plurality of integrated device dies. Similarly, the second element 804 can comprise a singulated element, such as a singulated integrated device die. In other arrangements, the second element 804 can comprise a carrier or substrate (e.g., a wafer). The embodiments disclosed herein can accordingly apply to wafer-to-wafer (W2W), die-to-die (D2D), or die-to-wafer (D2W) bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

As explained herein, the first and second elements 802 and 804 can be directly bonded to one another without an adhesive, which is different from a deposition process and results in a structurally different interface compared to a deposition. In one application, a width of the first element 802 in the bonded structure is similar to a width of the second element 804. In some other embodiments, a width of the first element 802 in the bonded structure 800 is different from a width of the second element 804. Similarly, the width or area of the larger element in the bonded structure may be at least 10% larger than the width or area of the smaller element. The first and second elements 802 and 804 can accordingly comprise non-deposited elements. Further, directly bonded structures 800, unlike deposited layers, can include a defect region along the bond interface 818 in which nanometer-scale voids (nanovoids) are present. The nanovoids may be formed due to activation of the bonding surfaces 812a and 812b (e.g., exposure to a plasma). As explained above, the bond interface 818 can include concentration of materials from the activation and/or last chemical treatment processes. For example, in embodiments that utilize a nitrogen plasma for activation, a nitrogen peak can be formed at the bond interface 818. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen peak can be formed at the bond interface 818. In some embodiments, the bond interface 818 can comprise silicon oxynitride, silicon oxycarbonitride, or silicon carbonitride. As explained herein, the direct bond can comprise a covalent bond, which is stronger than van Der Waals bonds. The bonding layers 808a and 808b can also comprise polished surfaces that are planarized to a high degree of smoothness.

In various embodiments, the metal-to-metal bonds between the conductive features 806a and 806b can be joined such that metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during annealing. The bond interface 818 can extend substantially entirely to at least a portion of the bonded conductive features 806a and 806b, such that there is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b, for example, as described in U.S. Pat. No. 11,195,748, which is incorporated by reference herein in its entirety and for all purposes.

Beneficially, the use of the hybrid bonding techniques described herein can enable extremely fine pitch between adjacent conductive features 806a and 806b, and/or small pad sizes. For example, in various embodiments, the pitch p (i.e., the distance from edge-to-edge or center-to-center, as shown in FIG. 13) between adjacent conductive features 806a (or 806b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

As described above, the non-conductive bonding layers 808a, 808b can be directly bonded to one another without an adhesive and, subsequently, the bonded structure 800 can be annealed. Upon annealing, the conductive features 806a and 806b can expand and contact one another to form a metal-to-metal direct bond. In some embodiments, the materials of the conductive features 806a and 806b can interdiffuse during the annealing process.

### EXAMPLES EMBODIMENTS

In various embodiments, the invention is a method comprising providing a frame element having a bulk portion, a first bonding layer disposed on a first surface of the bulk portion and at least partially defining a first side of the frame element, and a second bonding layer on a second surface of the bulk portion and at least partially defining a second side of the frame element opposite the first side, forming an opening through the frame element such that the opening extends through the first bonding layer, the bulk portion, and the second bonding layer, directly bonding a first element to the first bonding layer of the frame element over the opening without an intervening adhesive, and directly bonding a second element to the second bonding layer of the frame element over the opening without an intervening adhesive to define a cavity.

In one aspect of the invention, forming the opening comprises etching through the first bonding layer in a first direction from the first side of the frame element towards the second side of the frame element, and etching at least partially through the bulk portion in the first direction. Forming the opening may further comprise etching completely through the bulk portion in the first direction, and through the second bonding layer in the first direction.

In another aspect of the invention, forming the opening further comprises etching partially through the bulk portion in a second direction from the second side of the frame element towards the first side of the frame element.

In another aspect of the invention, forming the opening further comprises etching through the second bonding layer in a second direction from the second side of the frame element towards the first side of the frame element.

In another aspect of the invention, before forming the opening, the frame element is mounted to a support. The support is a rigid substrate with an organic adhesive. Alternatively, the support is a rigid substrate with or an inorganic bonding layer comprising silicon nitride. The inorganic bonding layer has a bonding energy in the range of 100 mJ/m² to 1000 mJ/m². Or the inorganic bonding layer comprises a volatile component that weakens bonding strength when heated. Alternatively, the support is a support tape.

In another aspect of the invention, directly bonding the first element to the first bonding layer of the frame element is performed after mounting the frame element to a support. After directly bonding the first element to the first bonding layer of the frame element, the support is removed from the frame element.

In another aspect of the invention, directly bonding the second element to the second bonding layer of the frame element is performed after removing the support from the frame element.

In another aspect of the invention, a vent hole is formed through at least a portion of the frame element to the cavity. The vent hole may be formed after directly bonding the first element to the first bonding layer of the frame element.

In another aspect of the invention, directly bonding the first element to the first bonding layer of the frame element comprises directly bonding conductive contact features of the first element to corresponding conductive contact features of the frame element without an adhesive.

In another aspect of the invention, directly bonding the second element to the second bonding layer of the frame element comprises directly bonding conductive contact features of the second element to corresponding conductive contact features of the frame element without an adhesive.

In another aspect of the invention, directly bonding the first element to the first bonding layer of the frame element comprises directly bonding a nonconductive bonding layer of the first element to a nonconductive bonding layer of the frame element.

In another aspect of the invention, a conductive through substrate via (TSV) is provided through the frame element, wherein the TSV comprises at least one of copper, nickel, tungsten, aluminum, or polysilicon. The conductive contact features comprise the same material as the TSV. Alternatively, the conductive contact features comprise a different material from the TSV. A width of the TSV is larger than a width of the conductive contact features. Alternatively, the width of the TSV is smaller than a width of the conductive contact features. More than one conductive contact feature connect to the TSV in the frame element at the first side and the second side.

In another aspect of the invention, a redistribution layer (RDL) conductive trace is disposed between the conductive contact features and the TSV.

In other embodiments, the invention is a frame element comprising an opening extending from a first side of the frame element to a second side opposite the first side, a bulk portion, a first bonding layer disposed on a first surface of the bulk portion and at least partially defining the first side of the frame element, and a second bonding layer on a second surface of the bulk portion and at least partially defining the second side of the frame element opposite the first side, wherein the opening extends through the first bonding layer, the bulk portion, and the second bonding layer, wherein the bulk portion comprises a first sidewall of the opening, the first sidewall comprising a first etch signature indicative of a first etch process in a first direction from the first side of the frame element towards the second side of the frame, and wherein the first bonding layer comprises a second sidewall of the opening, the second sidewall comprising a second etch signature indicative of a second etch process in the first direction.

In one aspect of the invention, the second bonding layer comprises a third sidewall of the opening, the third sidewall comprising a third etch signature indicative of a third etch process in the first direction. The second and third sidewalls are tapered in the same orientation. Further, the second and third sidewalls taper inwardly along the first direction. Alternatively, the second and third sidewalls taper outwardly along the first direction.

In another aspect of the invention, the second bonding layer comprises a third sidewall of the opening, the third sidewall comprising a third etch signature indicative of a third etch process in a second direction from the second side of the frame element towards the first side of the frame.

In another aspect of the invention, the bulk portion comprises a fourth sidewall of the opening, the fourth sidewall comprising a fourth etch signature indicative of a fourth etch process in the second direction.

In another aspect of the invention, the first and fourth sidewalls meet at a junction, and the junction projects radially inward relative to respective surfaces of the first and fourth sidewalls.

In another aspect of the invention, the second and third sidewalls are tapered in an opposite orientation.

In another aspect of the invention, the second and third sidewalls are laterally misaligned in a third direction that is transverse to the first direction.

In another aspect of the invention, any of the first, second, third, and fourth etch signatures comprises respective striations in the corresponding first, second, third, and fourth sidewalls.

In another aspect of the invention, any of the first, second, third, and fourth etch signatures comprises respective tapering angles in the corresponding first, second, third, and fourth sidewalls.

In another aspect of the invention, the bulk portion comprises a semiconductor material. The semiconductor portion comprises silicon.

In another aspect of the invention, the first bonding layer comprises a first nonconductive bonding layer with a first conductive contact feature at least partially embedded in the first nonconductive bonding layer. The second bonding layer comprises a second nonconductive bonding layer with a second conductive contact feature at least partially embedded in the second nonconductive bonding layer.

In another aspect of the invention, a conductive through substrate via (TSV) extends through the frame element, the TSV including or connected to the first and second conductive contact features. The TSV comprises at least one of copper, nickel, tungsten, aluminum, or polysilicon. The conductive contact features comprise the same material as the TSV. Alternatively, the conductive contact features comprise a different material from the TSV. A width of the TSV is larger than a width of the conductive contact features. Alternatively, the width of the TSV is smaller than a width of the conductive contact features. More than one conductive contact feature connect to the TSV in the frame element at the first side and the second side.

In another aspect of the invention, a redistribution layer (RDL) conductive trace is disposed between the conductive contact features and the TSV.

In some embodiments, the invention is a bonded structure comprising the frame element as described above, the bonded structure comprising a first element directly bonded to the first side of the frame element without an intervening adhesive and a second element directly bonded to the second side of the frame element without an intervening adhesive, the bonded structure comprising a cavity at least partially defined by the opening.

In one aspect of the invention, a third conductive contact feature of the first element is directly bonded to the first conductive contact feature of the frame element without an adhesive. A fourth conductive contact feature of the second element is directly bonded to the second conductive contact feature of the frame element.

In another aspect of the invention, the first nonconductive bonding layer of the frame element is directly bonded to a third nonconductive bonding layer of the first element. The second nonconductive bonding layer of the frame element is directly bonded to a fourth nonconductive bonding layer of the second element.

In another aspect of the invention, one or more devices are mounted to or formed with at least one of the first and second elements, the one or more devices extending into or exposed to the cavity. The one or more devices comprises an integrated device die.

In another aspect of the invention, a vent hole extends from the cavity to outside environs.

In another aspect of the invention, a width of the opening is in a range of 0.5 mm to 30 mm.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method comprising:
providing a frame element having a bulk portion, a first bonding layer disposed on a first surface of the bulk portion and at least partially defining a first side of the frame element, and a second bonding layer on a second surface of the bulk portion and at least partially defining a second side of the frame element opposite the first side;
forming an opening through the frame element such that the opening extends through the first bonding layer, the bulk portion, and the second bonding layer;
directly bonding a first element to the first bonding layer of the frame element over the opening without an intervening adhesive; and
directly bonding a second element to the second bonding layer of the frame element over the opening without an intervening adhesive to define a cavity.

2. The method of claim 1, wherein forming the opening comprises:
etching through the first bonding layer in a first direction from the first side of the frame element towards the second side of the frame element; and
etching at least partially through the bulk portion in the first direction.

3. The method of claim 2, wherein forming the opening comprises etching completely through the bulk portion in the first direction.

4. The method of claim 2, wherein forming the opening comprises etching through the second bonding layer in the first direction.

5. The method of claim 2, wherein forming the opening further comprises etching through the second bonding layer and partially through the bulk portion in a second direction from the second side of the frame element towards the first side of the frame element.

6. The method of any one of claims 1, further comprising, before forming the opening, mounting the frame element to a support.

7. The method of claim 6, wherein mounting the frame to a support comprises mounting the frame element to a rigid substrate with an organic adhesive.

8. The method of claim 6, wherein mounting the frame to a support comprises mounting the frame element to a tape.

9. The method of claim 6, wherein mounting the frame to a support comprises directly bonding the frame element to a rigid substrate without an adhesive.

10. The method of claim 9, wherein the substrate comprises an inorganic bonding layer comprising silicon nitride.

11. The method of claims 6, wherein directly bonding the first element to the first bonding layer of the frame element is performed after mounting the frame element to a support.

12. The method of claim 11, further comprising, after directly bonding the first element to the first bonding layer of the frame element, removing the support from the frame element.

13. The method of claim 12, wherein directly bonding the second element to the second bonding layer of the frame element is performed after removing the support from the frame element.

14. The method of claims 1, wherein directly bonding the first element to the first bonding layer of the frame element comprises directly bonding conductive contact features of the first element to corresponding conductive contact features of the frame element without an adhesive, wherein directly bonding the second element to the second bonding layer of the frame element comprises directly bonding conductive contact features of the second element to corresponding conductive contact features of the frame element without an adhesive.

15. The method of claim 14, further comprising providing a conductive through substrate via (TSV) through the frame element, wherein the TSV comprises a material selected from a group consisting of copper, nickel, tungsten, aluminum, or polysilicon.

16. The method of 15, wherein a redistribution layer (RDL) conductive trace is disposed between the conductive contact features and the TSV.

17. A frame element comprising:
an opening extending from a first side of the frame element to a second side opposite the first side;
a bulk portion;
a first bonding layer disposed on a first surface of the bulk portion and at least partially defining the first side of the frame element; and
a second bonding layer on a second surface of the bulk portion and at least partially defining the second side of the frame element opposite the first side,
wherein the opening extends through the first bonding layer, the bulk portion, and the second bonding layer,
wherein the bulk portion comprises a first sidewall of the opening, the first sidewall comprising a first etch signature indicative of a first etch process in a first direction from the first side of the frame element towards the second side of the frame, and
wherein the first bonding layer comprises a second sidewall of the opening, the second sidewall comprising a second etch signature indicative of a second etch process in the first direction.

18. The frame element of claim 17, wherein the second bonding layer comprises a third sidewall of the opening, the third sidewall comprising a third etch signature indicative of a third etch process in the first direction.

19. A bonded structure comprising the frame element of claims 17, the bonded structure comprising a first element directly bonded to the first side of the frame element without an intervening adhesive and a second element directly bonded to the second side of the frame element without an intervening adhesive, the bonded structure comprising a cavity at least partially defined by the opening.

20. The bonded structure of claims 19, further comprise one or more devices mounted to or formed with at least one of the first and second elements, the one or more devices extending into or exposed to the cavity.
